(19) United States
(12) Patent Application Publication
(10) Pub. No.: US 2026/0352969 A1
(43) Pub. Date: Nov. 5, 2026

(54) SOLID-STATE IMAGING ELEMENT

(71) Applicant: SONY SEMICONDUCTOR SOLUTIONS CORPORATION, KANAGAWA (JP)

(72) Inventors: MASAHIRO TSUKAMOTO, KANAGAWA (JP); KANAE OMORI, KANAGAWA (JP)

(21) Appl. No.: 19/485,422

(22) PCT Filed: Apr. 12, 2024
(86) PCT No.: PCT/JP2024/014794

§ 371 Date: Nov. 18, 2025

(30) Foreign Application Priority Data
May 26, 2023 (JP) 2023-087118

(51) Int. Cl. H04N 25/47; H04N 25/703; H04N 25/709

(52) U.S. Cl. CPC H04N 25/47; H04N 25/703; H04N 25/709

(57) ABSTRACT

To improve signal quality in a solid-state imaging element in which a synchronous pixel and an asynchronous pixel that detects an address event are arranged. A solid-state imaging element includes a pixel region and a non-grayscale pixel that does not correspond to a grayscale pixel. A predetermined number of grayscale pixels are arranged in the pixel region. The grayscale pixel generates a grayscale signal corresponding to the amount of charge generated by photoelectric conversion. In addition, a trench isolation (TI) having a pattern different from that of the pixel region is formed in the non-grayscale pixel. Additionally, the non-grayscale pixel is a pixel different from the grayscale pixel.

### TECHNICAL FIELD

The present technology relates to a solid-state imaging element. Specifically, the present technology relates to a solid-state imaging element that detects that an amount of change in a light amount exceeds a threshold.

### BACKGROUND ART

Heretofore, a synchronous solid-state imaging element that captures image data (frames) in synchronization with a synchronization signal such as a vertical synchronization signal is used in an imaging device or the like. In this general synchronous solid-state imaging element, image data can be acquired only in each cycle (for example, 1/60 seconds) of a synchronization signal. On the other hand, in an asynchronous sensor that detects, for each pixel address, that an amount of change in a light amount of the pixel exceeds a threshold as an address event in real time, data can be generated and output at a much higher speed than the synchronous type. Such a high-speed sensor is called an event-based vision sensor (EVS) or a dynamic vision sensor (DVS). For example, a solid-state imaging element in which asynchronous pixels of the same system as EVS are arranged in addition to synchronous pixels has been proposed (see, for example, Patent Document 1.).

### CITATION LIST

### Patent Document

Patent Document 1: Japanese Patent Application Laid-Open No. 2021-197649

### SUMMARY OF THE INVENTION

### Problems to be Solved by the Invention

In the above-described conventional technology, both the synchronous pixel and the asynchronous pixel are arranged, so that both high-quality image data due to the synchronous pixel and high-speed data due to the asynchronous pixel are output. However, in the above-described solid-state imaging element, when a pixel signal is read from a synchronous pixel via a vertical signal line, the potential of the vertical signal line fluctuates, and the potential fluctuation is transmitted to an adjacent asynchronous pixel due to capacitive coupling in some cases. Further, due to variations in rear deep trench isolation (RDTI), characteristics of pixels may vary. Due to these factors, signal quality may be deteriorated.

The present technology has been made in view of such a situation, and an object of the present technology is to improve signal quality in a solid-state imaging element in which a synchronous pixel and an asynchronous pixel that detects an address event are arranged.

### Solutions to Problems

The present technology has been made to solve the above-described problems, and a first aspect thereof provides a solid-state imaging element including a pixel region in which a predetermined number of grayscale pixels for generating a grayscale signal according to an amount of charge generated by photoelectric conversion are arranged, and a non-grayscale pixel not corresponding to the grayscale pixel and in which a trench isolation (TI) having a pattern different from that of the pixel region is formed. This brings about an effect that signal quality is improved.

The non-grayscale pixel may be a detection pixel that detects, as an address event, that an amount of change in a photocurrent generated by photoelectric conversion exceeds a predetermined threshold. This brings about an effect that an address event is detected.

Furthermore, in the first aspect, the TI may include a full trench isolation (FTI), and the FTI may insulate a grayscale-side well that is a well of the grayscale pixel and a detection-side well that is a well of the detection pixel. This brings about an effect that the detection accuracy of an address event is improved.

Furthermore, in the first aspect, the detection pixel may include a photoelectric conversion element and a current-voltage conversion unit, the current-voltage conversion unit may include a predetermined number of log transistors that convert the photocurrent into a logarithmic voltage, and a predetermined number of transimpedance amplifiers that invert and amplify the logarithmic voltage, and the FTI may be formed on an outer periphery of the detection pixel when viewed from an optical axis direction. This brings about an effect that an address event is detected on the basis of a logarithmic voltage according to the photocurrent.

Furthermore, in the first aspect, the log transistor may be arranged in the detection pixel when viewed from the optical axis direction. This brings about an effect that an address event is detected on the basis of a logarithmic voltage according to the photocurrent.

Furthermore, in the first aspect, the log transistor and the transimpedance amplifier may be arranged in the detection pixel when viewed from the optical axis direction. This brings about an effect that an address event is detected on the basis of a logarithmic voltage according to the photocurrent.

Furthermore, in the first aspect, the FTI may be formed on an outer periphery of a region in which a pair of grayscale pixels are arranged, an outer periphery of a region in which the log transistor is arranged, and an outer periphery of a region in which the transimpedance amplifier is arranged. This brings about an effect that periodicity of a structure for separating pixels is secured.

Furthermore, in the first aspect, at least one of the predetermined number of log transistors may be diode-connected. This brings about an effect of reducing the number of transistors.

Furthermore, in the first aspect, the detection pixel may include first and second detection pixels sharing a current-voltage conversion unit, and the current-voltage conversion unit may include a predetermined number of log transistors that convert the photocurrent into a logarithmic voltage, and a predetermined number of transimpedance amplifiers that invert and amplify the logarithmic voltage. This brings about an effect that the circuit scale is reduced.

Furthermore, in the first aspect, the grayscale pixel may include a transfer transistor that transfers charge from a photoelectric conversion element to a floating diffusion layer, a reset transistor that initializes the floating diffusion layer, an amplification transistor that amplifies a voltage of the floating diffusion layer, and a selection transistor that outputs a signal of the voltage as the grayscale signal according to a predetermined selection signal, the detection pixel may include a log transistor that converts the photocurrent into a logarithmic voltage, and a transimpedance amplifier that inverts and amplifies the logarithmic voltage, and the transfer transistor, the reset transistor, the amplification transistor, the selection transistor, the log transistor, and the transimpedance amplifier may be dispersedly arranged in a first layer and a second layer. This brings about an effect of facilitating pixel miniaturization.

Furthermore, in the first aspect, the transfer transistor, the log transistor, and the transimpedance amplifier may be arranged in the first layer, and the reset transistor, the amplification transistor, and the selection transistor may be arranged in the second layer. This brings about an effect of facilitating pixel miniaturization.

Furthermore, in the first aspect, the transfer transistor and the log transistor may be arranged in the first layer, and the reset transistor, the amplification transistor, the selection transistor, and the transimpedance amplifier may be arranged in the second layer. This brings about an effect of facilitating pixel miniaturization.

Furthermore, in the first aspect, the detection pixel may include a log transistor that converts the photocurrent into a logarithmic voltage, and a transimpedance amplifier that inverts and amplifies the logarithmic voltage, among the detection-side wells, a well of the log transistor may be connected to a first power supply line, and among the detection-side wells, a well of the transimpedance amplifier and the grayscale-side well may be commonly connected to a second power supply line. This brings about an effect that the potential fluctuation of the detection pixel is suppressed.

Furthermore, in the first aspect, the power supply voltage of the first power supply line may be a negative voltage lower than a predetermined reference voltage. This brings about an effect that the potential fluctuation of the detection pixel is further suppressed.

Furthermore, in the first aspect, an area of the detection pixel may be the same as that of the pixel region, and a TI of the detection pixel may be reduced as compared with the pixel region. This brings about an effect that variations in characteristics of the detection pixels caused by variations in TI are suppressed.

Furthermore, in the first aspect, the TI may be an RDTI. This brings about an effect that variations in characteristics of the detection pixels caused by variations in RDTI are suppressed.

Furthermore, in the first aspect, the TI may be an FTI. This brings about an effect that variations in characteristics of the detection pixels caused by variations in FTI are suppressed.

Furthermore, in the first aspect, an area of the detection pixel is the same as that of the pixel region, and the pixel region may be divided into a plurality of unit regions. This brings about an effect that the area of the detection pixel is enlarged.

Furthermore, in the first aspect, the detection pixel may include first and second detection pixels sharing a current-voltage conversion unit, and the TI may be formed on an outer periphery of the first detection pixel and an outer periphery of the second detection pixel. This brings about an effect of facilitating miniaturization.

Furthermore, in the first aspect, a predetermined number of the grayscale pixels and a predetermined number of the non-grayscale pixels may be arranged in a two-dimensional lattice pattern on a predetermined light receiving surface, each of the grayscale pixels may include a photoelectric conversion element, and an area of a photoelectric conversion element of the grayscale pixel adjacent to the non-grayscale pixel on the light receiving surface may be different from an area of a photoelectric conversion element of the grayscale pixel not adjacent to the non-grayscale pixel. This brings about an effect that image quality is improved.

Furthermore, in the first aspect, the non-grayscale pixel may be a detection pixel that detects, as an address event, that an amount of change in a photocurrent generated by photoelectric conversion exceeds a predetermined threshold. This brings about an effect that an address event is detected.

Furthermore, in the first aspect, an area of a photoelectric conversion element of the grayscale pixel adjacent to the non-grayscale pixel and arranged in the same row or column as the non-grayscale pixel may be different from an area of a photoelectric conversion element of the grayscale pixel not adjacent to the non-grayscale pixel. This brings about an effect that image quality is improved.

Furthermore, in the first aspect, shapes of photoelectric conversion elements of a pair of grayscale pixels adjacent to the non-grayscale pixel and arranged in the same row or column may be asymmetric. This brings about an effect that image quality is improved.

### BRIEF DESCRIPTION OF DRAWINGS

FIG. 1 is a block diagram illustrating a configuration example of an imaging device according to a first embodiment of the present technology.

FIG. 2 is a diagram illustrating an example of a laminated structure of a solid-state imaging element according to the first embodiment of the present technology.

FIG. 3 is a plan view illustrating a configuration example of a pixel chip according to the first embodiment of the present technology.

FIG. 4 is a block diagram illustrating a configuration example of a circuit chip according to the first embodiment of the present technology.

FIG. 5 is a block diagram illustrating a configuration example of an EVS pixel according to the first embodiment of the present technology.

FIG. 6 is a circuit diagram illustrating a configuration example of a shared block and an EVS pixel according to the first embodiment of the present technology.

FIG. 7 is a circuit diagram illustrating a configuration example of a shared block and an EVS pixel in a case where a floating diffusion layer is not shared according to the first embodiment of the present technology.

FIG. 8 is a circuit diagram illustrating a configuration example of a buffer, a subtractor, and a quantizer according to the first embodiment of the present technology.

FIG. 9 is a plan view illustrating an example of a transistor layout in a pixel chip according to the first embodiment of the present technology.

FIG. 10 is a plan view illustrating another example of a transistor layout in the pixel chip according to the first embodiment of the present technology.

FIG. 11 is a diagram illustrating an example of a layout in a case where a region is divided in a pixel according to the first embodiment of the present technology.

FIG. 12 is an example of a cross-sectional view of a pixel when viewed from the Y-axis direction according to the first embodiment of the present technology.

FIG. 13 is an example of a cross-sectional view of a pixel when viewed from the X-axis direction according to the first embodiment of the present technology.

FIG. 14 is a cross-sectional view illustrating an example of a structure of a well according to the first embodiment of the present technology.

FIG. 15 is a cross-sectional view illustrating an example of a structure of a well according to a comparative example.

FIG. 16 is a plan view illustrating an example of a method of wiring a power supply line and a vertical signal line according to the first embodiment of the present technology.

FIG. 17 is a circuit diagram illustrating a configuration example of a shared block according to a first modification of the first embodiment of the present technology.

FIG. 18 is a plan view illustrating an example of a transistor layout when the FTI is formed on the outer periphery of only one EVS pixel according to the first modification of the first embodiment of the present technology.

FIG. 19 is a plan view illustrating an example of a transistor layout when an FTI is formed on the outer periphery of a region where a log transistor is disposed in an EVS pixel according to the first modification of the first embodiment of the present technology.

FIG. 20 is a plan view illustrating an example of a transistor layout when the FTI is formed on the outer periphery of each EVS pixel according to the first modification of the first embodiment of the present technology.

FIG. 21 is a plan view illustrating another example of a transistor layout when the FTI is formed on the outer periphery of each EVS pixel according to the first modification of the first embodiment of the present technology.

FIG. 22 is a plan view illustrating an example of a transistor layout when the FTI is formed on the outer periphery of each of the EVS pixel and the grayscale pixel according to the first modification of the first embodiment of the present technology.

FIG. 23 is a diagram illustrating an example of a layout in a case where a region is divided in a pixel according to the first modification of the first embodiment of the present technology.

FIG. 24 is an example of a cross-sectional view of a pixel according to a second modification of the first embodiment of the present technology.

FIG. 25 is a plan view illustrating an example of a transistor layout of each of an upper layer and a lower layer according to the second modification of the first embodiment of the present technology.

FIG. 26 is a plan view illustrating another example of a transistor layout of each of an upper layer and a lower layer according to the second modification of the first embodiment of the present technology.

FIG. 27 is a circuit diagram illustrating a configuration example of a current-voltage conversion unit according to a third modification of the first embodiment of the present technology.

FIG. 28 is a circuit diagram illustrating a configuration example of a current-voltage conversion unit according to a fourth modification of the first embodiment of the present technology.

FIG. 29 is a circuit diagram illustrating a configuration example of a current-voltage conversion unit according to a fifth modification of the first embodiment of the present technology.

FIG. 30 is a circuit diagram illustrating a configuration example of a shared block and an EVS pixel according to a second embodiment of the present technology.

FIG. 31 is a plan view illustrating an example of a method of wiring a power supply line and a vertical signal line according to the second embodiment of the present technology.

FIG. 32 is a circuit diagram illustrating a configuration example of a shared block and an EVS pixel according to a third embodiment of the present technology.

FIG. 33 is an example of an equivalent circuit of a current-voltage conversion unit according to the third embodiment of the present technology.

FIG. 34 is a diagram for describing an effect in a case where wells of log transistors are connected to a negative voltage node according to the third embodiment of the present technology.

FIG. 35 is a plan view illustrating an example of a method of wiring a power supply line and a vertical signal line according to the third embodiment of the present technology.

FIG. 36 is a plan view illustrating an example of a method of wiring a power supply line and a vertical signal line in a case where a plurality of EVS pixels shares a current-voltage conversion unit and the like according to the third embodiment of the present technology.

FIG. 37 is a plan view illustrating another example of a method of wiring a power supply line and a vertical signal line in a case where a plurality of EVS pixels shares a current-voltage conversion unit and the like according to the third embodiment of the present technology.

FIG. 38 is a circuit diagram illustrating a configuration example of a shared block according to a fourth embodiment of the present technology.

FIG. 39 is a plan view illustrating an example of an RDTI pattern according to a fifth embodiment of the present technology.

FIG. 40 is a plan view illustrating an example of a RDTI pattern in a case where the area of the EVS pixel is the same as the area of two unit regions according to the fifth embodiment of the present technology.

FIG. 41 is a plan view illustrating an example of a RDTI pattern in a case where the area of the EVS pixel is the same as the area of three unit regions according to the fifth embodiment of the present technology.

FIG. 42 is a plan view illustrating an example of a RDTI pattern in a case where the area of the EVS pixel is the same as the area of six unit regions according to the fifth embodiment of the present technology.

FIG. 43 is a plan view illustrating an example of a RDTI pattern in a case where the area of the EVS pixel is the same as the area of eight unit regions according to the fifth embodiment of the present technology.

FIG. 44 is a plan view illustrating an example of a RDTI pattern in a case where the area of the EVS pixel is the same as the area of eight unit regions according to the fifth embodiment of the present technology.

FIG. 45 is a plan view illustrating an example of a RDTI pattern in a case where the area of the EVS pixel is the same as the area of eight unit regions according to the fifth embodiment of the present technology.

FIG. 46 is a plan view illustrating an example of a RDTI pattern in a case where the area of the EVS pixel is the same as the area of eight unit regions according to the fifth embodiment of the present technology.

FIG. 47 is a plan view illustrating an example of an RDTI pattern of a comparative example.

FIG. 48 is an example of a cross-sectional view of the EVS pixels of the comparative example and the fifth embodiment of the present technology.

FIG. 49 is a plan view illustrating examples of FTI patterns of the first modification of the fifth embodiment of the present technology and a comparative example.

FIG. 50 is an example of a cross-sectional view of EVS pixels of a comparative example and a first modification of the fifth embodiment of the present technology.

FIG. 51 is a plan view illustrating an example of a layout and an RDTI pattern in a case where EVS pixels are arranged in the horizontal direction according to a second modification of the fifth embodiment of the present technology.

FIG. 52 is a plan view illustrating an example of a layout in a case where EVS pixels are arranged in an oblique direction according to the second modification of the fifth embodiment of the present technology.

FIG. 53 is a plan view illustrating an example of a layout in a case where EVS pixels are arranged in an oblique direction according to the second modification of the fifth embodiment of the present technology.

FIG. 54 is a plan view illustrating an example of a layout in a case where EVS pixels are arranged in the vertical direction according to the second modification of the fifth embodiment of the present technology.

FIG. 55 is a plan view illustrating an example of a layout in a case where EVS pixels are arranged in an oblique direction according to the second modification of the fifth embodiment of the present technology.

FIG. 56 is a plan view illustrating an example of a layout in a case where EVS pixels are arranged in an oblique direction according to the second modification of the fifth embodiment of the present technology.

FIG. 57 is a plan view illustrating an example of a layout in a case where EVS pixels are arranged in the horizontal direction adjacent to each other according to the second modification of the fifth embodiment of the present technology.

FIG. 58 is a plan view illustrating an example of a layout in a case where EVS pixels are arranged in the vertical direction adjacent to each other according to the second modification of the fifth embodiment of the present technology.

FIG. 59 is an example of a plan view of a pixel chip in a case where the sizes of EVS pixels in the row direction and the column direction are reduced according to the sixth embodiment of the present technology.

FIG. 60 is an example of a plan view of a pixel chip in a case where the sizes of EVS pixels in the row direction and the column direction are enlarged according to the sixth embodiment of the present technology.

FIG. 61 is an example of a plan view of a pixel chip in a case where the sizes of EVS pixels in the row direction are reduced according to the sixth embodiment of the present technology.

FIG. 62 is an example of a plan view of a pixel chip in a case where the sizes of EVS pixels in the column direction are reduced according to the sixth embodiment of the present technology.

FIG. 63 is an example of a plan view of a pixel chip in a case where the sizes of EVS pixels in the row direction are enlarged according to the sixth embodiment of the present technology.

FIG. 64 is an example of a plan view of a pixel chip in a case where the sizes of EVS pixels in the column direction are enlarged according to the sixth embodiment of the present technology.

FIG. 65 is an example of a plan view of a pixel chip in a case where the sizes of a pair of grayscale pixels arranged in the row direction are different from each other and the sizes of a pair of grayscale pixels arranged in the column direction are also different from each other in a sixth embodiment of the present technology.

FIG. 66 is an example of a plan view of a pixel chip in a case where the sizes of a pair of grayscale pixels arranged in the column direction are different from each other in the sixth embodiment of the present technology.

FIG. 67 is another example of a plan view of a pixel chip in a case where the sizes of a pair of grayscale pixels arranged in the column direction are different from each other in the sixth embodiment of the present technology.

FIG. 68 is a block diagram illustrating a schematic configuration example of a vehicle control system.

FIG. 69 is an explanatory diagram illustrating an example of an installation position of an imaging section.

### MODE FOR CARRYING OUT THE INVENTION

Hereinafter, modes for carrying out the present technology (hereinafter referred to as embodiments) will be described. The description will be given in the following order.
1. First embodiment (example in which well of grayscale pixel and well of EVS pixel are insulated)
2. Second embodiment (example in which well of grayscale pixel and well of EVS pixel are insulated and wells are connected to different power supply lines)
3. Third embodiment (example in which well of grayscale pixel and well of EVS pixel are insulated and negative voltage is applied to some wells)
4. Fourth embodiment (example in which well of the grayscale pixel and well of EVS pixel are insulated and two wells on input side are arranged nearby)
5. Fifth embodiment (example in which RDTI patterns of grayscale pixel and EVS pixel are different)
6. Sixth embodiment (example in which area of photoelectric conversion element of grayscale pixel adjacent to EVS pixel is different from that of non-adjacent grayscale pixel)
7. Example of application to mobile body

### 1. First Embodiment

### Configuration Example of Imaging Device

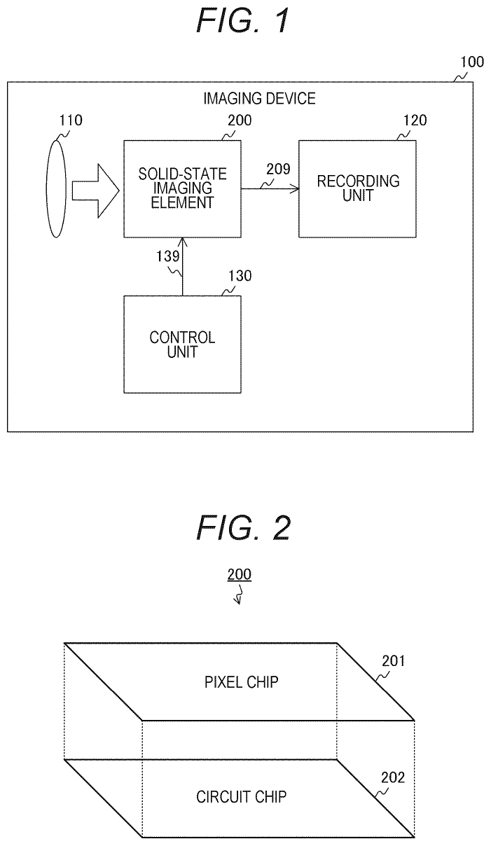

FIG. 1 is a block diagram illustrating a configuration example of an imaging device 100 according to a first embodiment of the present technology. The imaging device 100 includes an imaging lens 110, a solid-state imaging element 200, a recording unit 120, and a control unit 130. As the imaging device 100, a camera mounted on an industrial robot, an in-vehicle camera, and the like are assumed.

The imaging lens 110 condenses incident light and guides the light to the solid-state imaging element 200. The solid-state imaging element 200 photoelectrically converts incident light to capture image data. Furthermore, the solid-state imaging element 200 detects the presence or absence of an address event, generates a detection signal, and performs predetermined signal processing on the detection signal. The solid-state imaging element 200 outputs the processed data together with image data to the recording unit 120 via a signal line 209.

The recording unit 120 records data from the solid-state imaging element 200. The control unit 130 controls the solid-state imaging element 200 to capture image data.

### Configuration Example of Solid-state Imaging Element

FIG. 2 is a diagram illustrating an example of a laminated structure of the solid-state imaging element 200 according to the first embodiment of the present technology. The solid-state imaging element 200 includes a circuit chip 202 and a pixel chip 201 stacked on the circuit chip 202. These chips are electrically connected by, for example, Cu—Cu bonding. Note that in addition to the Cu—Cu bonding, the connection can be made using a via or a bump.

### Configuration Example of Pixel Chip

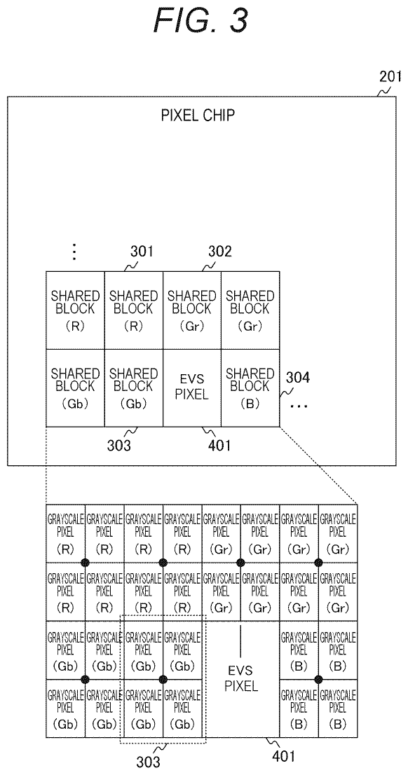

FIG. 3 is a plan view illustrating a configuration example of the pixel chip 201 according to the first embodiment of the present technology. Hereinafter, the pixel chip 201 is referred to as an upper chip, and the circuit chip 202 is referred to as a lower chip. A predetermined number of shared blocks such as shared blocks 301, 302, 303, and 304 and a predetermined number of EVS pixels 401 are arranged in the pixel chip 201.

In each shared block, a plurality of same colored grayscale pixels sharing a floating diffusion layer is arranged. For example, four pixels are arranged in two rows×two columns for each shared block. In the drawing, black circles indicate the floating diffusion layer. Furthermore, grayscale pixels that receive red incident light are arranged in the shared block 301, and grayscale pixels that receive green incident light are arranged in the shared blocks 302 and 303. Furthermore, grayscale pixels that receive blue incident light are arranged in the shared block 304. Note that the wavelength of light received by the grayscale pixel is not limited to the combination of red, green, and blue.

Here, the grayscale pixel generates charge by photoelectric conversion on incident light, and outputs a grayscale signal corresponding to the amount of charge. Furthermore, the EVS pixel 401 generates a photocurrent by photoelectric conversion on incident light, and detects, as an address event, that an amount of change in the photocurrent exceeds a predetermined threshold.

Moreover, the address event includes, for example, an on-event indicating that an amount of increase in luminance exceeds an upper limit threshold and an off-event indicating that an amount of decrease in luminance falls below a lower limit threshold less than the upper limit threshold. Additionally, each detection signal output from the EVS pixel 401 includes an on-event detection signal indicating presence or absence of an on-event and an off-event detection signal indicating presence or absence of an off-event.

For example, four of eight adjacent blue grayscale pixels are replaced with the EVS pixels 401. Note that grayscale pixels other than blue can be replaced with the EVS pixels 401. Furthermore, the number of grayscale pixels to be replaced with the EVS pixels 401 is not limited to four. Furthermore, the EVS pixel 401 is an example of a detection pixel described in the claims.

### Configuration Example of Circuit Chip

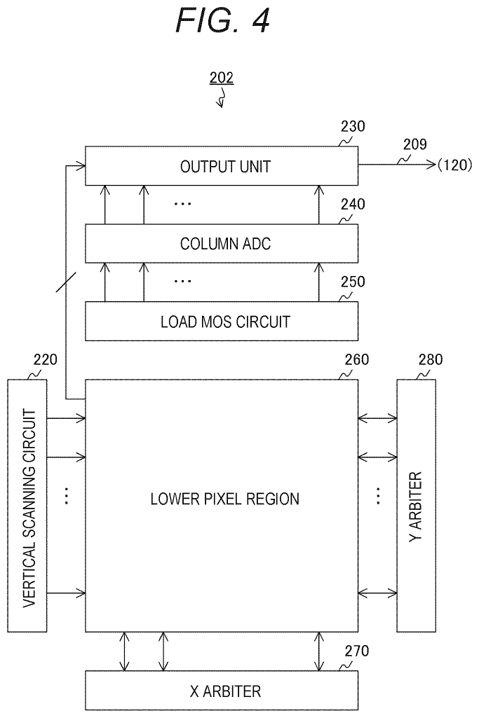

FIG. 4 is a block diagram illustrating a configuration example of the circuit chip 202 according to the first embodiment of the present technology. The circuit chip 202 includes a vertical scanning circuit 220, an output unit 230, a column analog to digital converter (ADC) 240, and a load metal-oxide-semiconductor (MOS) circuit 250. Furthermore, the circuit chip 202 includes a lower pixel region 260, an X arbiter 270, and a Y arbiter 280.

The vertical scanning circuit 220 drives each of the pixels (the grayscale pixel and the EVS pixel 401) to output a grayscale signal and a detection signal.

In the lower pixel region 260, a circuit of a part of the EVS pixel 401 is arranged. When an address event occurs, each of the EVS pixels 401 supplies a request to the Y arbiter 280 and the X arbiter 270, and supplies a detection signal to the output unit 230 on the basis of arbitration results thereof.

The Y arbiter 280 arbitrates a request from each of the rows of the EVS pixels 401 and returns a response on the basis of the arbitration result. The X arbiter 270 arbitrates a request from each of the columns of the EVS pixels 401 and returns a response on the basis of the arbitration result.

In the load MOS circuit 250, a load MOS current source connected to the vertical signal line of the column is arranged for each column of the shared block.

In the column ADC 240, an ADC is arranged for each column of the shared block. The ADC converts an analog pixel signal from the corresponding column into a digital signal and supplies the digital signal to the output unit 230.

The output unit 230 processes the digital signal from the column ADC 240 and the detection signal from the EVS pixel 401, and outputs the processing result to the recording unit 120. For example, the output unit 230 performs various types of signal processing such as correlated double sampling (CDS) processing on the digital signal, and generates image data in which the processed signals are arranged. Furthermore, the output unit 230 performs image recognition processing and the like on the detection signal.

### Configuration Example of Pixel

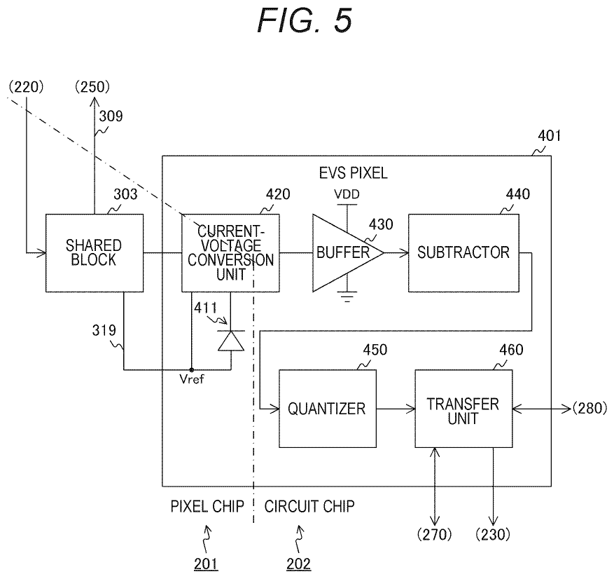

FIG. 5 is a block diagram illustrating a configuration example of the EVS pixel 401 according to the first embodiment of the present technology. The EVS pixel 401 includes a photoelectric conversion element 411, a current-voltage conversion unit 420, a buffer 430, a subtractor 440, a quantizer 450, and a transfer unit 460.

In addition, the adjacent shared block 303, one end (such as an anode) of the photoelectric conversion element 411, and the current-voltage conversion unit 420 are commonly connected to a power supply line 319 of a reference voltage Vref (such as 0 volt).

Furthermore, a shared block such as the shared block 303, the photoelectric conversion element 411, and a part of the current-voltage conversion unit 420 are arranged in the pixel chip 201. On the other hand, the rest of the current-voltage conversion unit 420, the buffer 430, the subtractor 440, the quantizer 450, and the transfer unit 460 are arranged in the circuit chip 202.

The photoelectric conversion element 411 generates a photocurrent by photoelectric conversion on incident light. As the photoelectric conversion element 411, for example, a photodiode is used.

The current-voltage conversion unit 420 converts the photocurrent generated by the photoelectric conversion element 411 into a voltage. The current-voltage conversion unit 420 supplies a voltage to the buffer 430.

The buffer 430 outputs the voltage from the current-voltage conversion unit 420 to the subtractor 440. The buffer 430 can improve the driving force for driving the subsequent stage. In addition, the buffer 430 can ensure noise isolation associated with a switching operation in the subsequent stage.

The subtractor 440 obtains an amount of change in voltage by a subtraction operation in accordance with a drive signal from the vertical scanning circuit 220. The subtractor 440 supplies a differential signal indicating the amount of change to the quantizer 450.

The quantizer 450 compares the differential signal from the subtractor 440 with a threshold. The quantizer 450 supplies the comparison result to the transfer unit 460 as a signal indicating the presence or absence of an address event.

The transfer unit 460 transfers the detection signal to the output unit 230. When an address event is detected, the transfer unit 460 supplies a request for requesting transmission of the detection signal to the X arbiter 270 and the Y arbiter 280. Then, upon receiving a response to the request from these arbiters, the transfer unit 460 supplies the detection signal to the output unit 230.

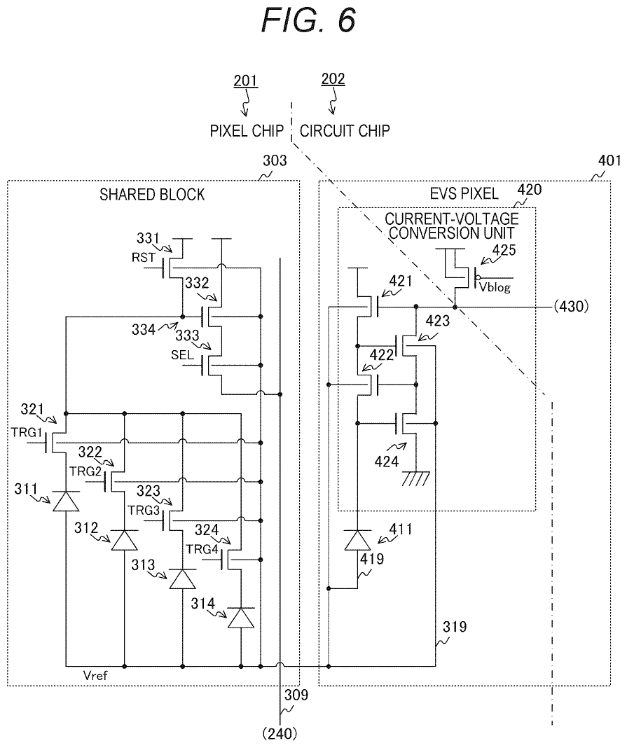

FIG. 6 is a circuit diagram illustrating a configuration example of the shared block 303 and the EVS pixel 401 according to the first embodiment of the present technology.

The shared block 303 includes photoelectric conversion elements 311, 312, 313, and 314, transfer transistors 321, 322, 323, and 324, a reset transistor 331, an amplification transistor 332, a selection transistor 333, and a floating diffusion layer 334. As various transistors such as the transfer transistor 321, for example, n-channel metal oxide semiconductor (nMOS) transistors are used.

The transfer transistor 321 transfers charge from the photoelectric conversion element 311 to the floating diffusion layer 334 in accordance with a transfer signal TRG1 from the vertical scanning circuit 220. The transfer transistor 322 transfers charge from the photoelectric conversion element 312 to the floating diffusion layer 334 in accordance with a transfer signal TRG2 from the vertical scanning circuit 220. The transfer transistor 323 transfers charge from the photoelectric conversion element 313 to the floating diffusion layer 334 in accordance with a transfer signal TRG3 from the vertical scanning circuit 220. The transfer transistor 324 transfers charge from the photoelectric conversion element 314 to the floating diffusion layer 334 in accordance with a transfer signal TRG4 from the vertical scanning circuit 220.

The reset transistor 331 initializes the floating diffusion layer 334 in accordance with a reset signal RST received from the vertical scanning circuit 220. The floating diffusion layer 334 accumulates transferred charge and generates a voltage corresponding to the charge amount.

The amplification transistor 332 amplifies the voltage of the floating diffusion layer 334. The selection transistor 333 outputs a signal of the amplified voltage as a grayscale signal to the vertical signal line 309 in accordance with a selection signal SEL from the vertical scanning circuit 220.

In addition, the current-voltage conversion unit 420 includes log transistors 421 and 422, transimpedance amplifiers (TIA) 423 and 424, and a current source transistor 425. As the log transistor 421, the log transistor 422, the TIA 423, and the TIA 424, for example, nMOS transistors are used. As the current source transistor 425, for example, a p-channel MOS (pMOS) transistor is used. Note that the TIAs 423 and 424 are examples of a transimpedance amplifier described in the claims.

In addition, the photoelectric conversion element 411, the log transistors 421 and 422, and the TIAs 423 and 424 in the EVS pixel 401 are arranged in the pixel chip 201. The current source transistor 425 and the circuit subsequent to the buffer 430 are arranged in the circuit chip 202.

The log transistors 421 and 422 and the photoelectric conversion element 411 are connected in series between the power supply voltage and the reference voltage Vref. In addition, the current source transistor 425 and the TIAs 423 and 424 are connected in series between the power supply voltage and the reference voltage Vref.

In addition, a connection node of the log transistor 422 and the photoelectric conversion element 411 is connected to the gate of the TIA 424. A connection node of the log transistors 421 and 422 is connected to the gate of the TIA 423. A connection node of the current source transistor 425 and the TIA 423 is connected to the gate of the log transistor 421 and the buffer 430. A predetermined bias voltage Vblog is applied to the gate of the current source transistor 425. A connection node of the TIAs 423 and 424 is connected to the gate of the log transistor 422.

With the above-described circuit configuration, the log transistors 421 and 422 convert the photocurrent generated by the photoelectric conversion element 411 into a logarithmic voltage. Furthermore, the TIAs 423 and 424 inversely amplify the logarithmic voltage. Note that although the loop circuit including the log transistor and the TIA has two stages in the drawing, the loop circuit may have three or more stages.

In addition, each well of the anodes of the photoelectric conversion elements 311 to 314 and the back gate of the transistors in the shared block 303 is connected to the power supply line 319 of the reference voltage Vref. Each well of the anode of the photoelectric conversion element 411 and the back gate of the transistor other than the current source transistor 425 in the current-voltage conversion unit 420 is also commonly connected to the power supply line 319.

Note that in the drawing, the plurality of grayscale pixels shares the floating diffusion layer 334, but the present invention is not limited to this circuit configuration.

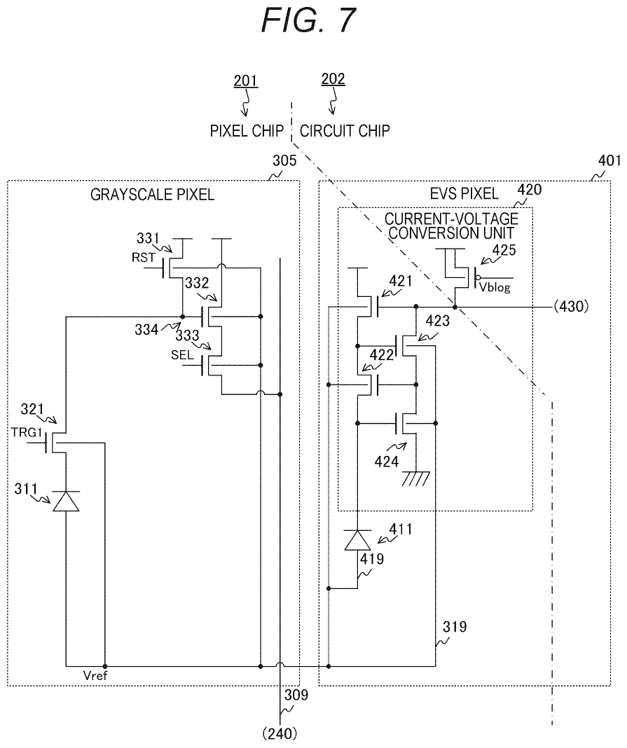

For example, as illustrated in FIG. 7, the photoelectric conversion element 311, the transfer transistor 321, the reset transistor 331, the amplification transistor 332, the selection transistor 333, and the floating diffusion layer 334 can be arranged in each grayscale pixel such as a grayscale pixel 305.

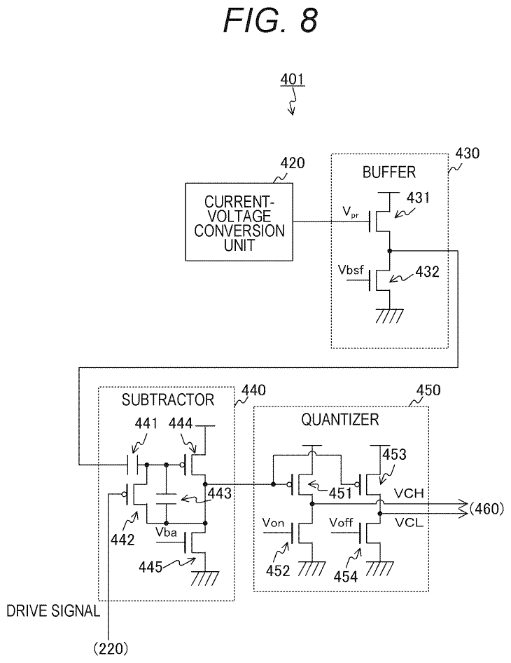

FIG. 8 is a circuit diagram illustrating a configuration example of the buffer 430, the subtractor 440, and the quantizer 450 according to the first embodiment of the present technology.

The buffer 430 includes nMOS transistors 431 and 432. The nMOS transistors 431 and 432 are connected in series between the power supply terminal and the ground terminal. A gate of the nMOS transistor 431 on the power supply side is connected to the current-voltage conversion unit 420, and a voltage Vₚᵣ is input thereto. A predetermined bias voltage Vbsf is applied to the gate of the nMOS transistor 432 on the ground side. Furthermore, a connection node of the nMOS transistors 431 and 432 is connected to the subtractor 440. With this connection, impedance conversion with respect to the voltage Vₚᵣ is performed.

The subtractor 440 includes capacitors 441 and 443, pMOS transistors 442 and 444, and an nMOS transistor 445.

The pMOS transistor 444 and the nMOS transistor 445 are connected in series between the power supply terminal and the ground terminal. These function as an inverter that inverts an input signal with the gate of the pMOS transistor 444 as the input terminal and a connection node of the pMOS transistor 444 and the nMOS transistor 445 as the output terminal.

One end of the capacitor 441 is connected to the output terminal of the buffer 430, and the other end is connected to the input terminal (i.e., the gate of the pMOS transistor 444) of the inverter. The capacitor 443 is connected in parallel with the inverter. The pMOS transistor 442 opens and closes a path connecting both ends of the capacitor 443 in accordance with a drive signal from the vertical scanning circuit 220.

The quantizer 450 includes pMOS transistors 451 and 453 and nMOS transistors 452 and 454.

The pMOS transistor 451 and the nMOS transistor 452 are connected in series between the power supply terminal and the ground terminal. The pMOS transistor 453 and the nMOS transistor 454 are also connected in series between the power supply terminal and the ground terminal. Furthermore, the gates of the pMOS transistors 451 and 453 are connected to the output terminal of the subtractor 440. A bias voltage Von indicating an upper limit threshold is applied to the gate of the nMOS transistor 452, and a bias voltage Voff indicating a lower limit threshold is applied to the gate of the nMOS transistor 454.

A connection node of the pMOS transistor 451 and the nMOS transistor 452 is connected to the transfer unit 460, and a voltage of this connection node is output as an on-event detection signal VCH. A connection node of the pMOS transistor 453 and the nMOS transistor 454 is also connected to the transfer unit 460, and a voltage of this connection node is output as an off-event detection signal VCL. With such a connection, the quantizer 450 outputs the high-level on-event detection signal VCH in a case where the differential signal exceeds the upper limit threshold, and outputs the low-level off-event detection signal VCL in a case where the differential signal falls below the lower limit threshold.

Note that the photoelectric conversion element 411 and a part of the current-voltage conversion unit 420 are arranged on the pixel chip 201, and the subsequent circuit is arranged on the circuit chip 202, but the circuits arranged on the chips are not limited to this configuration.

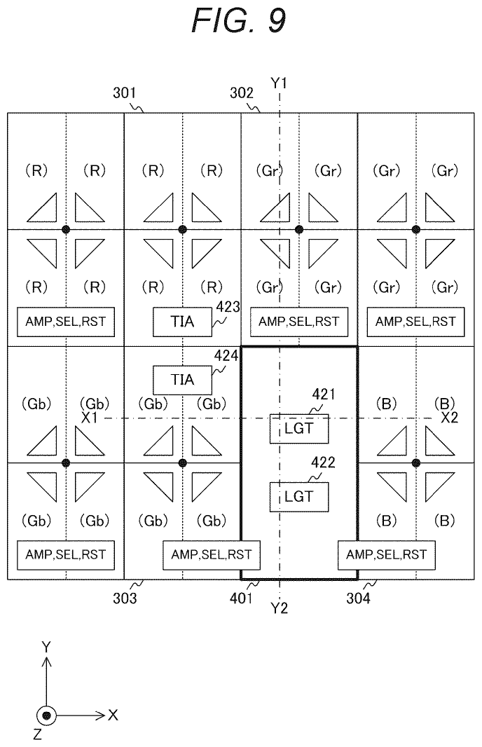

FIG. 9 is a plan view illustrating an example of a transistor layout in the pixel chip 201 according to the first embodiment of the present technology. An optical axis is referred to as a “Z axis”, and a predetermined axis perpendicular to the Z axis is referred to as an “X axis” below. An axis perpendicular to the X axis and the Z axis is referred to as a “Y axis”.

When viewed from the Z-axis (i.e., the optical axis) direction, the log transistors 421 and 422 are arranged in the EVS pixel 401. In addition, the TIAs 423 and 424 are arranged in a shared block adjacent to the EVS pixel 401. For example, the TIA 423 is arranged in the shared block 301 and the TIA 424 is arranged in the shared block 303. In addition, a corresponding transfer transistor is arranged in each of the shared blocks. In the drawing, a triangle represents a transfer transistor. In addition, the reset transistor 331, the amplification transistor 332, and the selection transistor 333 of each shared block are arranged along a predetermined direction (X axis or the like). In the drawing, “AMP, SEL, RST” indicates the amplification transistor 332, the selection transistor 333, and the reset transistor 331.

In addition, an RDTI is formed on the outer periphery of the shared block. The RDTI is also formed between the upper two pixels and the lower two pixels of the shared block. A thin solid line in the drawing indicates the RDTI. On the other hand, an FTI is formed on the outer periphery of the EVS pixel 401. A thick solid line in the drawing indicates the FTI. The depths of the RDTI and the FTI will be described later. As described above, the trench isolation (TI) pattern of the EVS pixel 401 is different from the TI pattern of the shared block.

Note that in the drawing, the TIAs 423 and 424 are arranged in a shared block, and the log transistors 421 and 422 are arranged in the EVS pixel 401, but the present invention is not limited to this configuration.

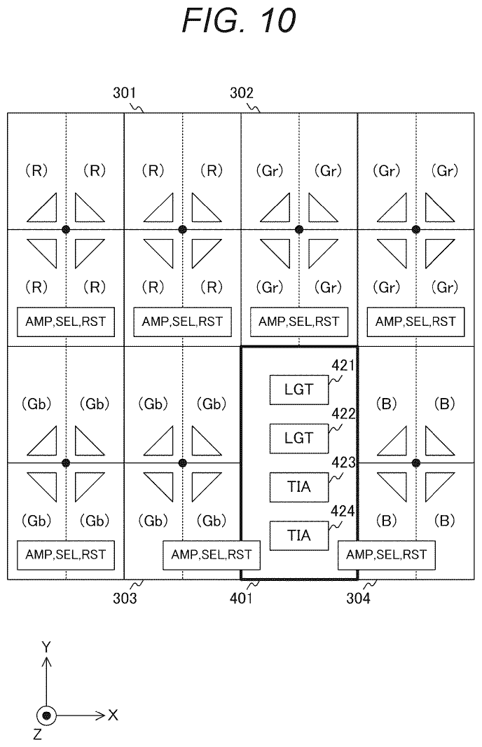

As illustrated in FIG. 10, it is also possible to arrange all of the log transistors 421 and 422 and the TIAs 423 and 424 in the EVS pixel 401.

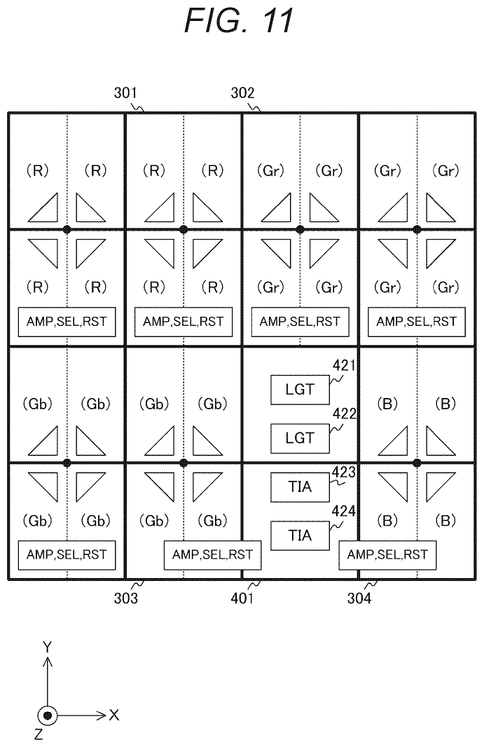

As illustrated in FIG. 11, in the layout illustrated in FIG. 10, it is also possible to form the FTI on the outer peripheries of the pair of grayscale pixels and the outer peripheries of the region in which the log transistors are arranged and the region in which the TIAs are arranged in the EVS pixel 401. By forming the FTI in this manner, it is possible to secure the periodicity of the FTI which is a structure for separating pixels while suppressing potential fluctuation via the well.

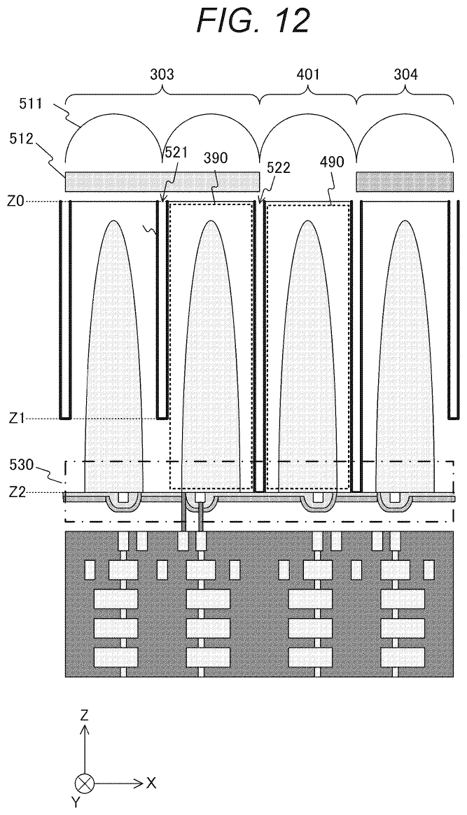

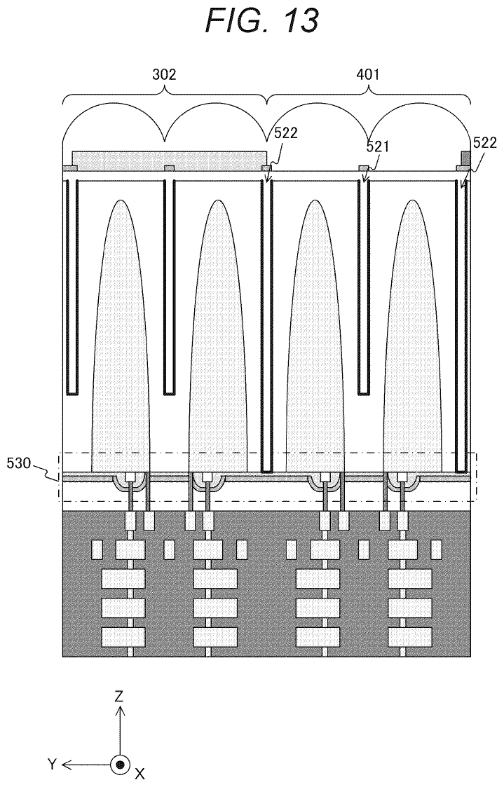

FIG. 12 is an example of a cross-sectional view when the pixel chip 201 is cut along a line segment X1-X2 in FIG. 9 and viewed from the Y-axis direction. A microlens 511 is arranged above each pixel. Furthermore, in the shared block 303, a color filter 512 is formed below the microlens 511. Furthermore, in each grayscale pixel in the shared block 303, a well 390 is formed below the color filter 512. In the EVS pixel 401, a well 490 is formed below the microlens 511. A lower portion of these wells is used as a transistor arrangement region 530.

An FTI 522 is formed between the well 390 of the grayscale pixel and the well 490 of the EVS pixel 401 to insulate them. On the other hand, an RDTI shallower than the FTI 522 is formed between the wells 390 of two adjacent grayscale pixels.

For example, assuming that the Z coordinate of an upper surface of the well is Z0, the Z coordinate of a lower surface is Z2, and the Z coordinate therebetween is Z1, an RDTI 521 extends from Z0 to Z1. On the other hand, the FTI 522 extends from Z0 to Z2.

Note that the well 390 is an example of a grayscale-side well described in the claims, and the well 490 is an example of a detection-side well described in the claims.

Here, a configuration in which a well 490 of an EVS pixel 401 is not insulated from a well 390 of the grayscale pixel by an FTI 522 and an RDTI 521 is formed on the outer periphery thereof is assumed as a comparative example. In this comparative example, in the circuit illustrated in FIG. 6, capacitive coupling occurs between a vertical signal line 309 and a power supply line 319. Then, when the grayscale signal is read from the grayscale pixel via the vertical signal line 309, the potential of the vertical signal line 309 fluctuates, and the potential fluctuation is transmitted to the EVS pixel 401 via the capacitive coupling. Due to the transmission of the potential fluctuation, a fluctuation occurs in the output voltage of a current-voltage conversion unit 420 of the EVS pixel 401, and the detection accuracy of the address event decreases.

In contrast to this comparative example, in FIG. 12, the FTI 522 insulates the well 490 in the EVS pixel 401 from the well 390 of the grayscale pixel. As a result, the potential fluctuation of the vertical signal line 309 is less likely to be transmitted to the EVS pixel 401, and a decrease in detection accuracy can be suppressed.

FIG. 13 is an example of a cross-sectional view when the pixel chip 201 is cut along the line segment Y1-Y2 in FIG. 9 and viewed from the Y-axis direction. As illustrated in the drawing, the FTI 522 is formed on the outer periphery of the well of the EVS pixel 401. Furthermore, in addition to the outer periphery of the shared block 302, the RDTI 521 is also formed in the EVS pixel 401 as necessary.

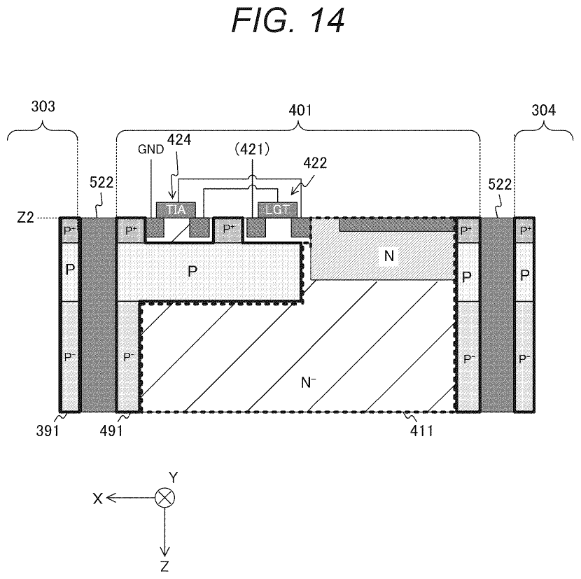

FIG. 14 is a cross-sectional view illustrating an example of a structure of a well according to the first embodiment of the present technology. The well of the EVS pixel 401 includes a P well 491 and an N well that is a part of the photoelectric conversion element 411. A region surrounded by a dotted line indicates a part of the photoelectric conversion element 411, and a region surrounded by a thick line indicates the P well 491. The P well 491 is arranged between various transistors such as the log transistor 422 and the TIA 424 and the photoelectric conversion element 411.

Moreover, the well of the grayscale pixel in the shared block 303 also includes a P well 391 and an N well.

The depth of the FTI 522 reaches Z2 on the lower surface of the P well. Therefore, the P well 391 of the grayscale pixel and the P well 491 of the EVS pixel 401 are insulated by the FTI 522. As a result, as described above, the potential fluctuation of the vertical signal line 309 is less likely to be transmitted to the EVS pixel 401, and a decrease in detection accuracy can be suppressed.

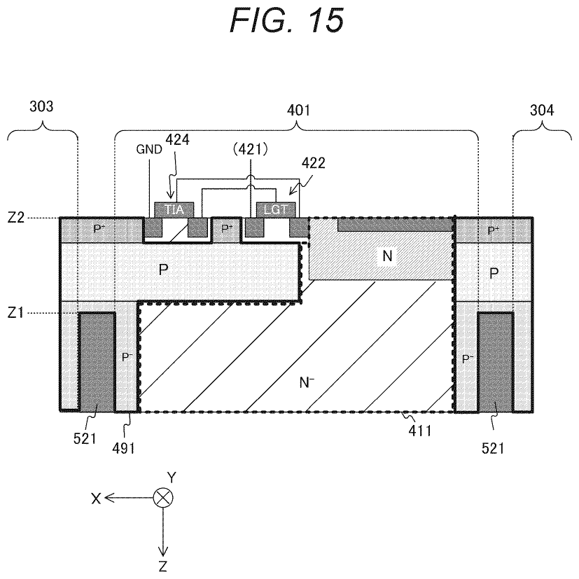

FIG. 15 is a cross-sectional view illustrating an example of a structure of a well according to a comparative example. In this comparative example, the FTI is not formed between an EVS pixel 401 and a grayscale pixel in an adjacent shared block 303, and an RDTI 521 shallower than the FTI is formed. Therefore, the wells of the EVS pixel 401 and the grayscale pixel are integrated and connected. In this configuration, as described above, the potential fluctuation is transmitted to the EVS pixel 401 via the capacitive coupling, the output voltage of a current-voltage conversion unit 420 of the EVS pixel 401 fluctuates, and the detection accuracy of the address event decreases.

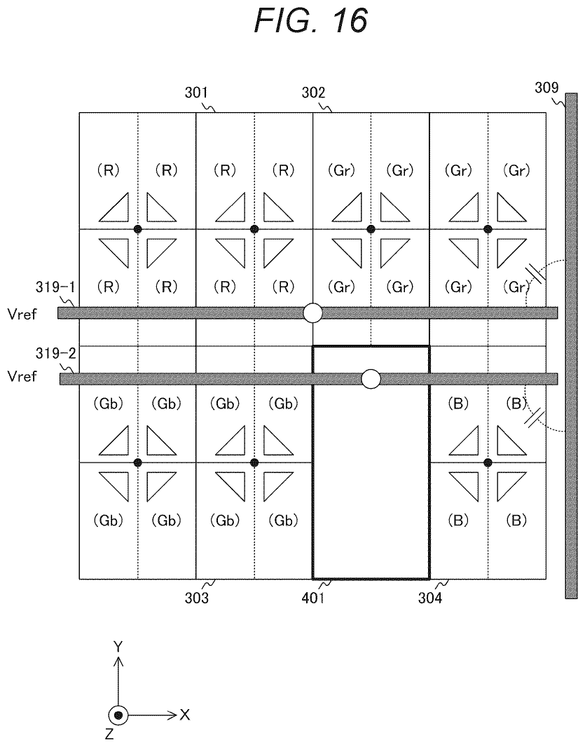

FIG. 16 is a plan view illustrating an example of a method of wiring power supply lines 319-1 and 319-2 and the vertical signal line 309 according to the first embodiment of the present technology. The vertical signal line 309 is wired along the Y-axis direction, and the power supply lines 319-1 and 319-2 of the reference voltage Vref are wired along the X-axis direction. The power supply line 319-1 is connected to the shared blocks 301 and 302, and the power supply line 319-2 is connected to the EVS pixel 401. White circles in the drawing indicate connection portions. A wiring capacitance may be generated between the power supply lines 319-1 and 319-2 and the vertical signal line 309.

As described above, according to the first embodiment of the present technology, since the FTI 522 insulates between the well 490 of the EVS pixel 401 and the well 390 of the grayscale pixel, it is possible to suppress a decrease in detection accuracy.

### First Modification

In the first embodiment described above, a detection circuit such as the current-voltage conversion unit 420 is provided for each EVS pixel, but with this configuration, it is difficult to miniaturize the EVS pixel. A solid-state imaging element 200 of a first modification of the first embodiment is different from that of the first embodiment in that a plurality of EVS pixels shares a circuit subsequent to a current-voltage conversion unit 420.

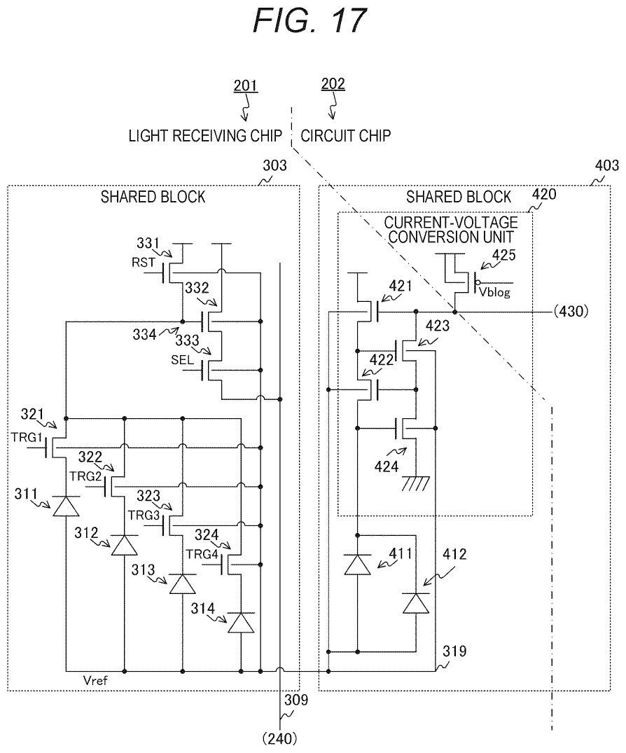

FIG. 17 is a circuit diagram illustrating a configuration example of shared blocks 303 and 403 according to the first modification of the first embodiment of the present technology. In the shared block 403, a plurality of EVS pixels is arranged.

For example, photoelectric conversion elements 411 and 412 and the current-voltage conversion unit 420 are arranged in the shared block 403. The cathodes of the photoelectric conversion elements 411 and 412 are commonly connected to the current-voltage conversion unit 420. The circuit in the shared block 403 illustrated in the drawing functions as two EVS pixels.

As illustrated in the drawing, since the plurality of EVS pixels shares the circuit subsequent to the current-voltage conversion unit 420, the circuit scale per pixel is reduced as compared with a case where the circuit is not shared, and miniaturization of the pixels is facilitated.

Note that in the drawing, the two EVS pixels share the current-voltage conversion unit 420 and the like, but three or more EVS pixels may share the current-voltage conversion unit 420 and the like.

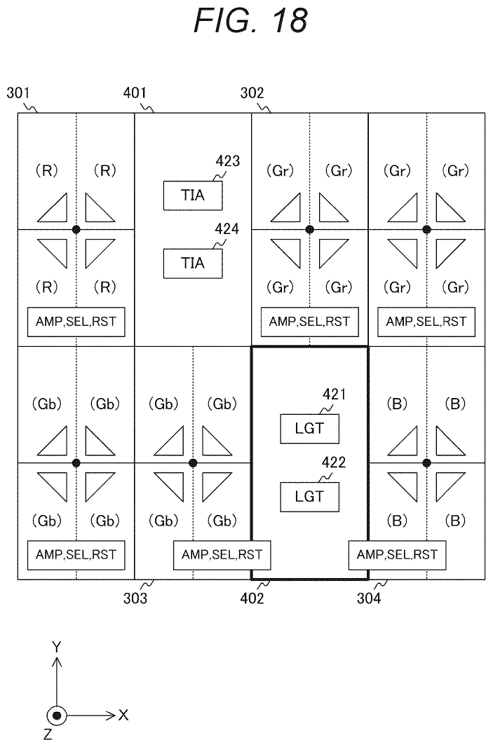

FIGS. 18 to 23 are plan views illustrating examples of a transistor layout in the first modification of the first embodiment. In these plan views, EVS pixels 401 and 402 indicate EVS pixels in a shared block 403. Note that the EVS pixels 401 and 402 are examples of first and second detection pixels described in the claims.

For example, as illustrated in FIG. 18, TIAs 423 and 424 may be arranged within an EVS pixel 401 and log transistors 421 and 422 may be arranged within an EVS pixel 402 as viewed in the Z-axis (optical axis) direction. In this case, for example, the FTI is formed on the outer periphery of the EVS pixel 402. Furthermore, the RDTI is formed on the outer periphery of the EVS pixel 401 and the grayscale pixel.

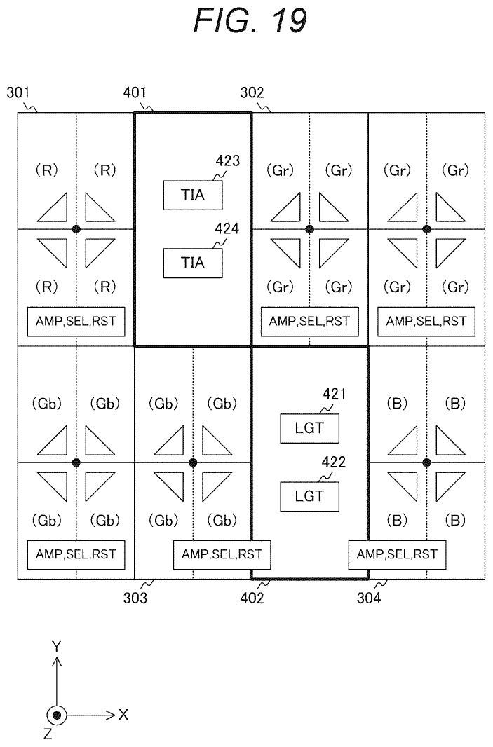

Furthermore, as illustrated in FIG. 19, a TIA and a log transistor can be arranged in each of EVS pixels 401 and 402. In this case, for example, the FTI is formed on the outer periphery of the region where the log transistors 421 and 422 are arranged in the EVS pixels 401 and 402.

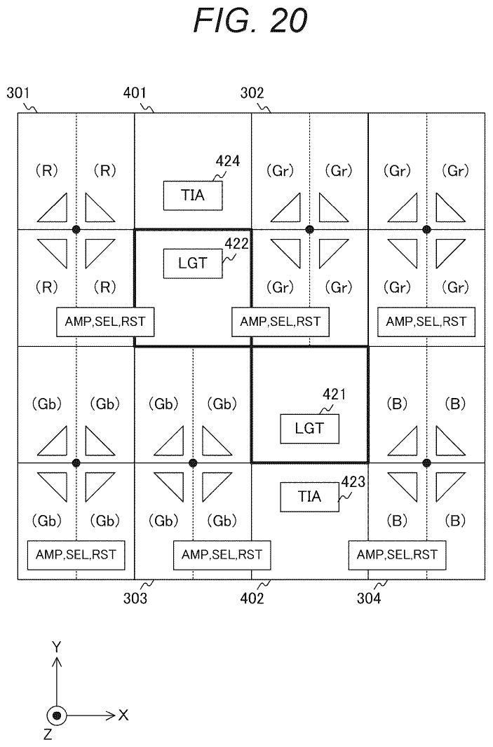

Alternatively, as illustrated in FIG. 20, in the transistor layout illustrated in FIG. 18, in addition to the EVS pixel 402, the FTI can also be formed on the outer periphery of the EVS pixel 401.

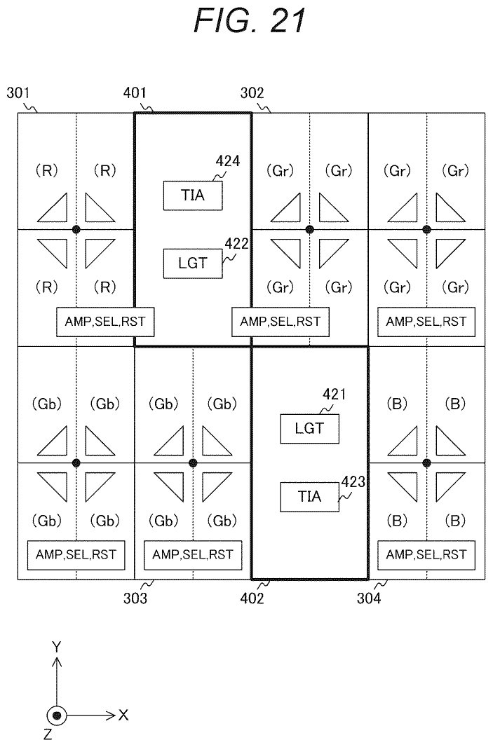

Alternatively, as illustrated in FIG. 21, in the transistor layout illustrated in FIG. 19, instead of separating the EVS pixel by the FTI, the FTI may be formed on the outer periphery of each of the EVS pixels 401 and 402.

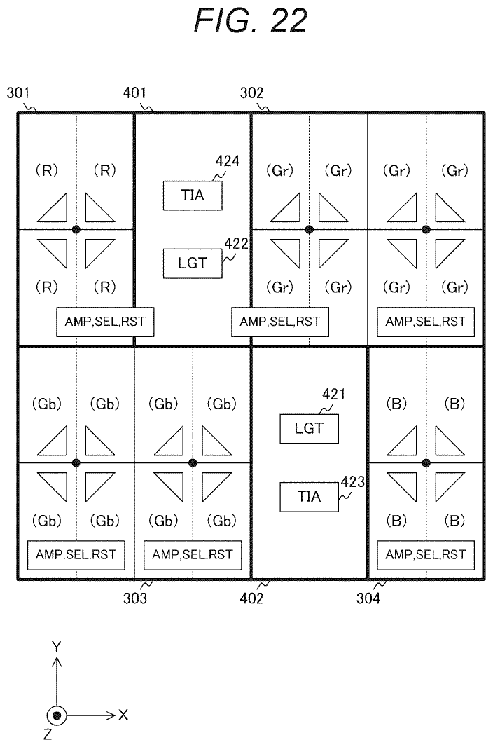

Alternatively, as illustrated in FIG. 22, in the layout illustrated in FIG. 21, the FTI can be further formed on the outer periphery of a predetermined number (one or two) of shared blocks in which grayscale pixels are arranged.

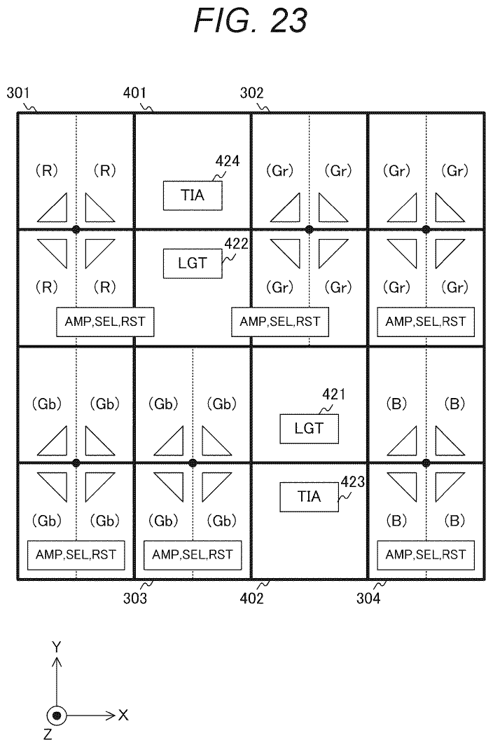

Furthermore, as illustrated in FIG. 23, in the layout illustrated in FIG. 22, the FTI can also be formed on the outer peripheries of the pair of grayscale pixels, and the region in which the log transistor is arranged and the region in which the TIA is arranged in the EVS pixels 401 and 402. By forming the FTI in this manner, it is possible to secure the periodicity of the structure (FTI) for separating pixels while suppressing potential fluctuation via the well.

As described above, according to the first modification of the first embodiment of the present technology, since the plurality of EVS pixels shares the circuit subsequent to the current-voltage conversion unit 420, miniaturization of the pixels is facilitated.

### Second Modification

In the above-described first embodiment, various transistors are arranged in the single-layer transistor arrangement region 530, but with this configuration, it is difficult to further miniaturize the pixel. A solid-state imaging element 200 of a second modification of the first embodiment is different from that of the first embodiment in that a transistor arrangement region 530 has a laminated structure.

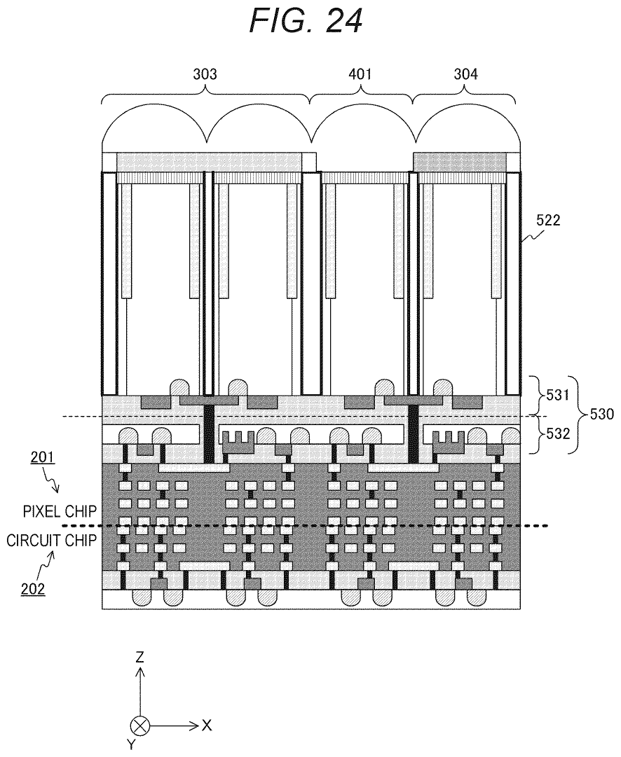

FIG. 24 is an example of a cross-sectional view of a pixel according to the second modification of the first embodiment of the present technology. In the second modification of the first embodiment, a transistor arrangement region 530 includes an upper layer 531 and a lower layer 532 that are stacked. Note that the upper layer 531 and the lower layer 532 are examples of a first layer and a second layer described in the claims.

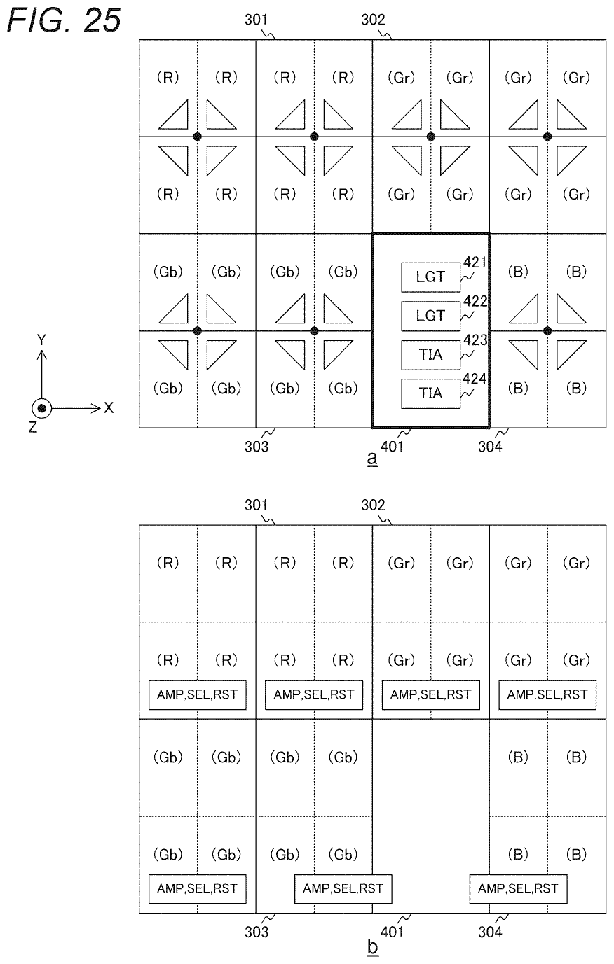

FIG. 25 is a plan view illustrating an example of a transistor layout of each of the upper layer 531 and the lower layer 532 according to the second modification of the first embodiment of the present technology. In the drawing, a illustrates an example of a layout of the upper layer 531, and b in the drawing illustrates an example of a layout of the lower layer 532.

As illustrated in a of the drawing, for example, a transfer transistor, log transistors 421 and 422, and TIAs 423 and 434 are arranged in the upper layer 531. The log transistors 421 and 422 and the TIAs 423 and 434 are arranged in an EVS pixel 401 when viewed from the Z-axis (optical axis) direction.

Furthermore, as illustrated in b of the drawing, for example, an amplification transistor 332 (AMP), a selection transistor 333 (SEL), and a reset transistor 331 (RST) are arranged in the lower layer 532.

As illustrated in a and b of the drawing, by forming the transistor arrangement region 530 in a laminated structure, the number of transistors per pixel is reduced when viewed from the Z-axis direction, and miniaturization of the pixel is facilitated.

Note that the layout of each layer is not limited to those illustrated in a and b in the drawing.

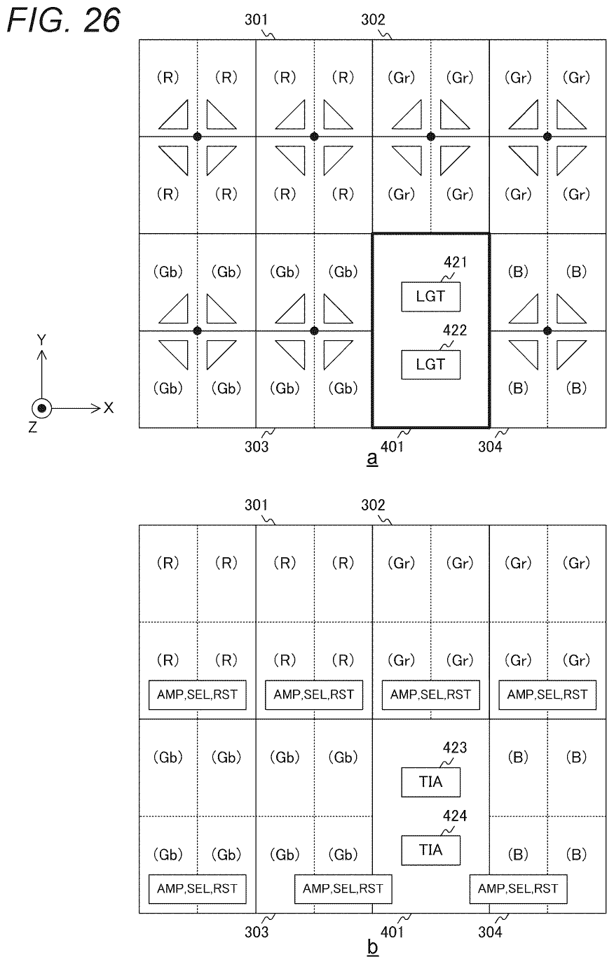

For example, a transfer transistor and log transistors 421 and 422 may be arranged in the upper layer 531 as illustrated in a of FIG. 26, and the remaining transistors may be arranged in the lower layer 532 as illustrated in b of FIG. 26.

Furthermore, the first modification is applicable to the second modification of the first embodiment.

As described above, according to the second modification of the first embodiment of the present technology, since the transistor arrangement region 530 has a laminated structure, miniaturization of pixels is facilitated.

### Third Modification

In the first embodiment described above, the loop circuit including the log transistor and the TIA has two stages, but the present technology is not limited to this configuration. A solid-state imaging element 200 according to a third modification of the first embodiment is different from that of the first embodiment in that a loop circuit is reduced to one stage.

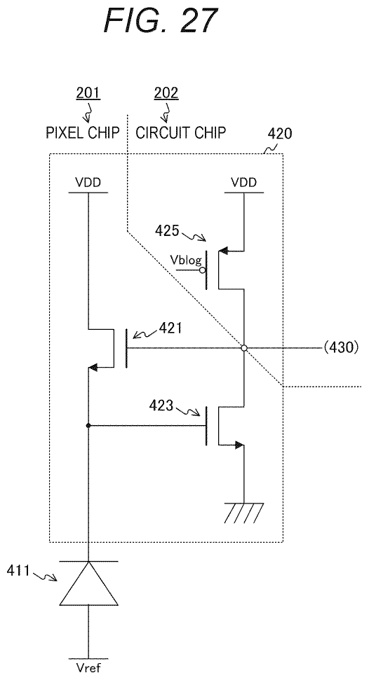

FIG. 27 is a circuit diagram illustrating a configuration example of a current-voltage conversion unit 420 according to the third modification of the first embodiment of the present technology. The current-voltage conversion unit 420 of the third modification of the first embodiment is different from that of the first embodiment in that the log transistor 422 and the TIA 424 are eliminated. Moreover, the source of a log transistor 421 and the gate of a TIA 423 are connected to a cathode of a photoelectric conversion element 411.

As illustrated in the drawing, the circuit scale of the EVS pixel can be reduced by reducing the log transistor 422 and the TIA 424.

Note that the first and second modifications are applicable to the third modification of the first embodiment.

As described above, according to the third modification of the first embodiment of the present technology, since the log transistor 422 and the TIA 424 are eliminated, the circuit scale of the EVS pixel can be reduced.

### Fourth Modification

In the third modification of the first embodiment described above, the loop circuit has two stages, but with this configuration, the gain of the current-voltage conversion unit 420 may be insufficient. A solid-state imaging element 200 of a fourth modification of the first embodiment is different from that of the third modification of the first embodiment in that a diode-connected log transistor 422 is inserted.

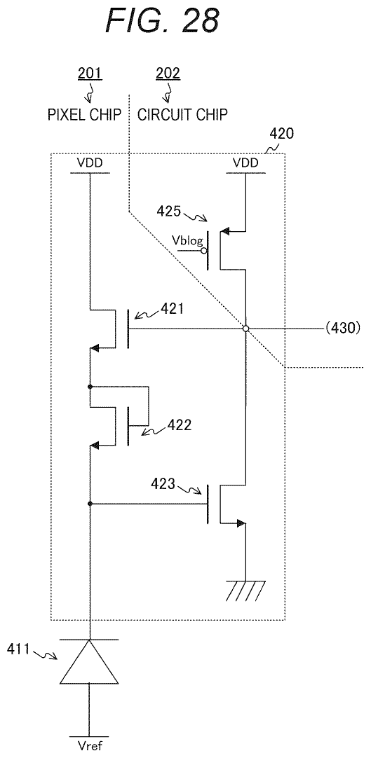

FIG. 28 is a circuit diagram illustrating a configuration example of a current-voltage conversion unit 420 according to the fourth modification of the first embodiment of the present technology. The current-voltage conversion unit 420 of the fourth modification of the first embodiment is different from that of the third modification of the first embodiment in that a diode-connected log transistor 422 is inserted.

A log transistor 421 and a TIA 423 constitute a loop circuit, and the log transistor 422 is inserted between the source of the log transistor 421 and the connection point of the TIA 423 and a photoelectric conversion element 411.

As illustrated in the drawing, by inserting the diode-connected log transistor 422, the gain of the current-voltage conversion unit 420 can be increased as compared with the third modification.

Note that the first and second modifications are applicable to the fourth modification of the first embodiment.

As described above, according to the fourth modification of the first embodiment of the present technology, since the diode-connected log transistor 422 is inserted, the gain of the current-voltage conversion unit 420 can be increased.

### Fifth Modification

In the fourth modification of the first embodiment described above, the diode-connected log transistor 422 is inserted, but with this configuration, the gain of the current-voltage conversion unit 420 may be insufficient. A solid-state imaging element 200 of a fifth modification of the first embodiment is different from that of the fourth modification of the first embodiment in that a diode-connected log transistor is further inserted.

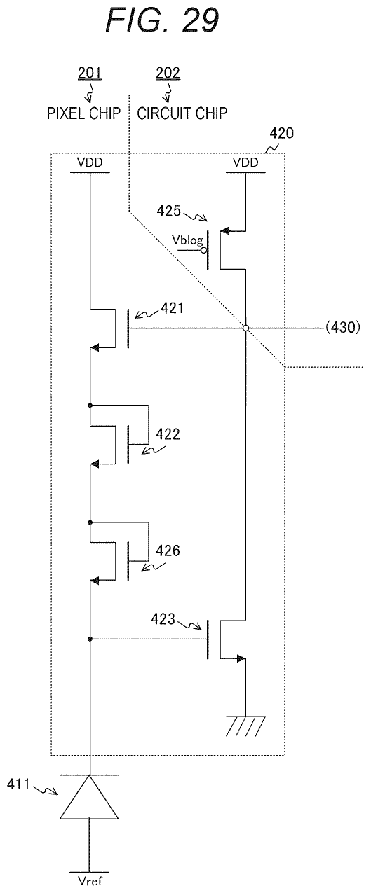

FIG. 29 is a circuit diagram illustrating a configuration example of a current-voltage conversion unit 420 according to the fifth modification of the first embodiment of the present technology. The current-voltage conversion unit 420 of the fifth modification of the first embodiment is different from that of the fourth modification of the first embodiment in that a diode-connected log transistor 426 is inserted. The log transistor 426 is inserted between the source of a log transistor 422 and the connection point of a TIA 423 and a photoelectric conversion element 411.

As illustrated in the drawing, by further inserting the diode-connected log transistor 426, the gain of the current-voltage conversion unit 420 can be increased as compared with the fourth modification.

Note that the first and second modifications are applicable to the fifth modification of the first embodiment. Additionally, in the drawing, the diode-connected log transistors are arranged in two stages, but may be arranged in three or more stages.

As described above, according to the fifth form example of the first embodiment of the present technology, since the diode-connected log transistor 426 is further inserted, the gain of the current-voltage conversion unit 420 can be increased.

### 2. Second Embodiment

In the first embodiment described above, the well of the grayscale pixel and the well of the EVS pixel 401 are commonly connected to the power supply line 319 of the reference voltage Vref, but with this configuration, a wiring capacitance may be generated between the power supply line 319 and the vertical signal line 309. A solid-state imaging element 200 of a second embodiment is different from that of the first embodiment in that the wells of log transistors 421 and 422 in an EVS pixel 401 and the well of the grayscale pixel are connected to different power supply lines.

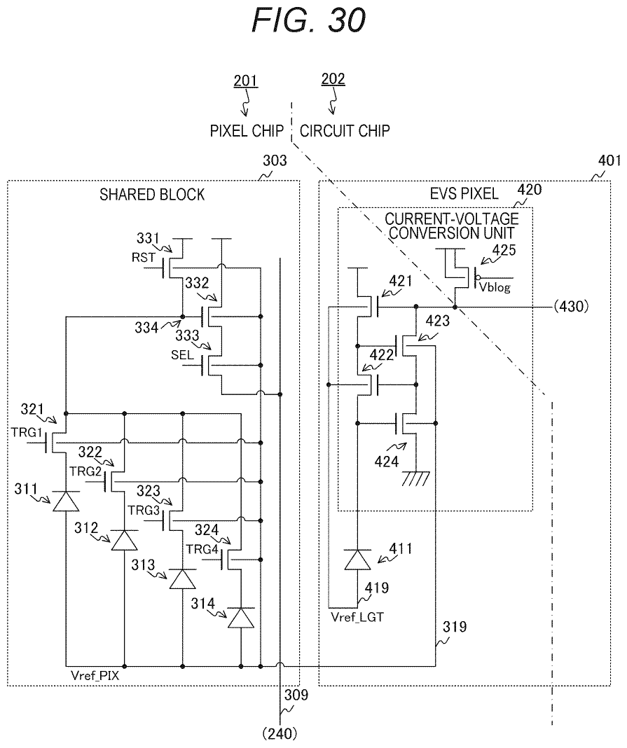

FIG. 30 is a circuit diagram illustrating a configuration example of a shared block 303 and the EVS pixel 401 according to the second embodiment of the present technology. In the second embodiment, the wells of the log transistors 421 and 422 are connected to a power supply line 419 of the reference voltage Vref_LGT, for example.

On the other hand, TIAs 423 and 424 and the wells of the adjacent grayscale pixels are connected to a power supply line 319 of a reference voltage Vref_PIX. The values of the reference voltage Vref_LGT and the reference voltage Vref_PIX may be substantially the same (0 volt or the like) or may be different.

Note that the power supply line 419 is an example of a first power supply line described in the claims, and the power supply line 319 is an example of a second power supply line described in the claims.

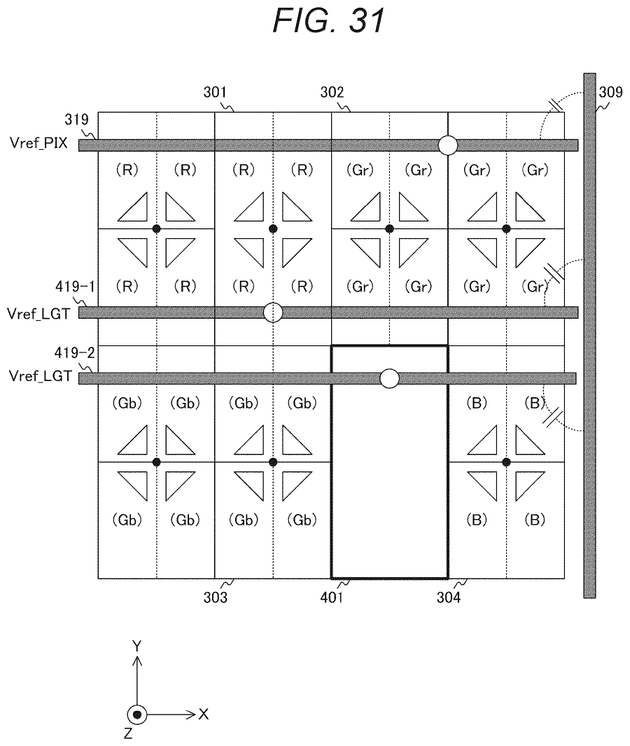

FIG. 31 is a plan view illustrating an example of a method of wiring the power supply line and a vertical signal line 309 according to the second embodiment of the present technology. The vertical signal line 309 is wired along the Y-axis direction, and the power supply line 319 of the reference voltage Vref_PIX and the power supply lines 419-1 and 419-2 of the reference voltage Vref_LGT are wired along the X-axis direction. The power supply line 319 is connected to a shared block, and the power supply line 419-1 is also connected to a shared block 301. The power supply line 419-2 is connected to an EVS pixel 401. A wiring capacitance may be generated between these power supply lines and the vertical signal line 309.

Note, however, that as illustrated in FIG. 30, the wells of the log transistors 421 and 422 and the wells of the grayscale pixels are connected to different power supply lines. With this configuration, the wiring capacitance between the power supply line 319 of the reference voltage Vref_PIX and the vertical signal line 309 can be reduced, and the detection accuracy of the address event can be improved accordingly.

Note that each of the first to fifth modifications of the first embodiment is applicable to the second embodiment.

As described above, according to the second embodiment of the present technology, since the wells of the log transistors 421 and 422 and the wells of the grayscale pixels are connected to different power supply lines, the detection accuracy of the address event can be improved.

### 3. Third Embodiment

In the second embodiment described above, the wells of the log transistors 421 and 422 are connected to the reference voltage Vref_LGT, but with this configuration, fluctuation of the output voltage of the current-voltage conversion unit 420 of the EVS pixel 401 cannot be sufficiently suppressed. A solid-state imaging element 200 of a third embodiment is different from that of the second embodiment in that the wells of the log transistors 421 and 422 are connected to a negative voltage.

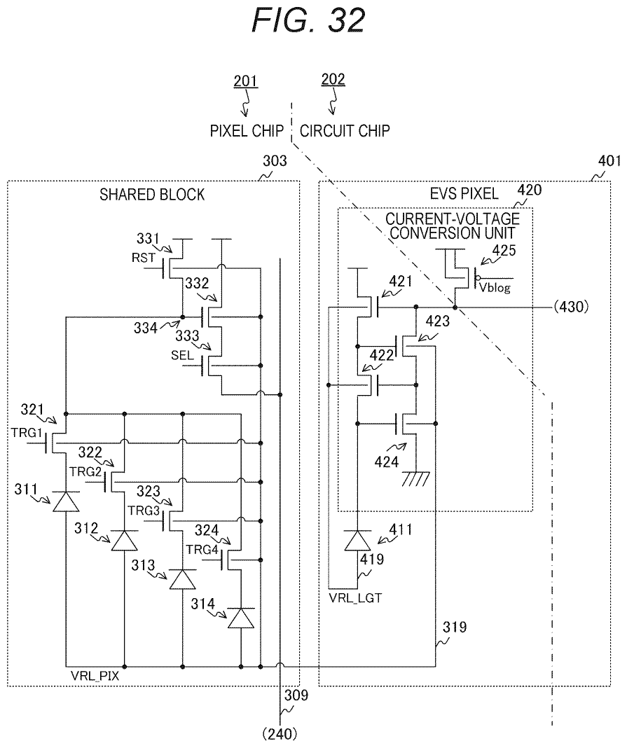

FIG. 32 is a circuit diagram illustrating a configuration example of a shared block 303 and an EVS pixel 401 according to the third embodiment of the present technology. In the third embodiment, a negative voltage VRL_LGT is applied to a power supply line 419 to which the wells of the log transistors 421 and 422 are connected. In addition, a negative voltage VRL_PIX is applied to a power supply line 319 to which the well of the grayscale pixel is connected. It is assumed that these values of VRL_LGT and VRL_PIX are lower than the reference voltage (0 volts). In addition, the values of VRL_LGT and VRL_PIX may be substantially the same or different.

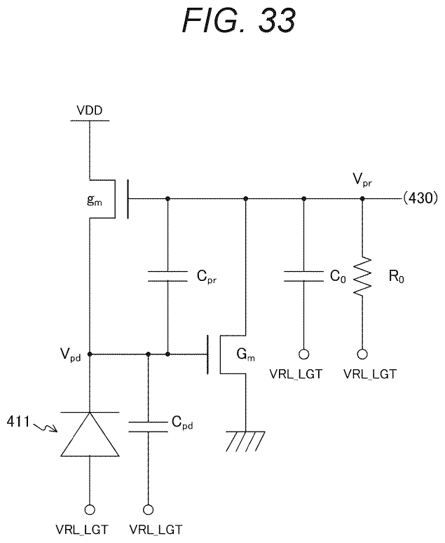

FIG. 33 is an example of an equivalent circuit of a current-voltage conversion unit 420 according to the third embodiment of the present technology. For convenience of description, assume that the loop circuit has one stage.

In addition, the potential of the input node of the current-voltage conversion unit 420 is defined as V_{pd}, and the capacitance of the input node is defined as C_{pd}. The transconductance of the log transistor 421 is defined as gₘ and the transconductance of a TIA 423 is defined as Gₘ. The capacitance between the gate of the log transistor 421 and the gate of the TIA 423 is defined as Cₚᵣ. The potential of the output node of the current-voltage conversion unit 420 is defined as Vₚᵣ, and the capacitance and resistance of the output node are defined as C₀ and R₀.

In this case, the potential fluctuation of the current-voltage conversion unit 420 is expressed by the following formula.

|Vₚᵣ/VRL_LGT|~{GₘR₀C_{pd}+(Cₚᵣ+C_{pd})}/{GₘR₀Cₚᵣ+(Cₚᵣ+C_{pd})}~C_{pd}/Cₚᵣ Formula 1

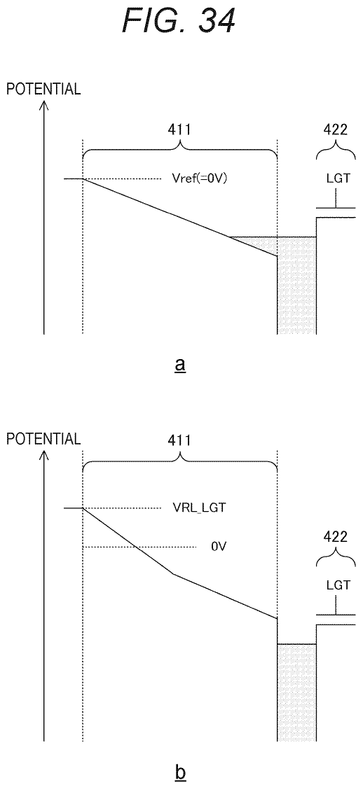

FIG. 34 is a diagram for describing an effect in a case where the wells of the log transistors 421 and 422 are connected to a negative voltage node according to the third embodiment of the present technology. In the drawing, a illustrates a potential diagram of the EVS pixel 401 in a case where the wells of the log transistors 421 and 422 are connected to the node of the reference voltage Vref (0 volt). In the drawing, b illustrates a potential diagram of the EVS pixel 401 in a case where the wells of the log transistors 421 and 422 are connected to the node of the negative voltage VRL_LGT. A gray portion indicates the capacitance C_{pd} of the input node of the current-voltage conversion unit 420.

As illustrated in a and b of the drawing, by setting the power supply voltage of the well to a negative voltage, the capacitance C_{pd} can be reduced as compared with the case of the reference voltage. According to Formula 1, when the capacitance C_{pd} decreases, the potential fluctuation of the current-voltage conversion unit 420 decreases as compared with the first embodiment.

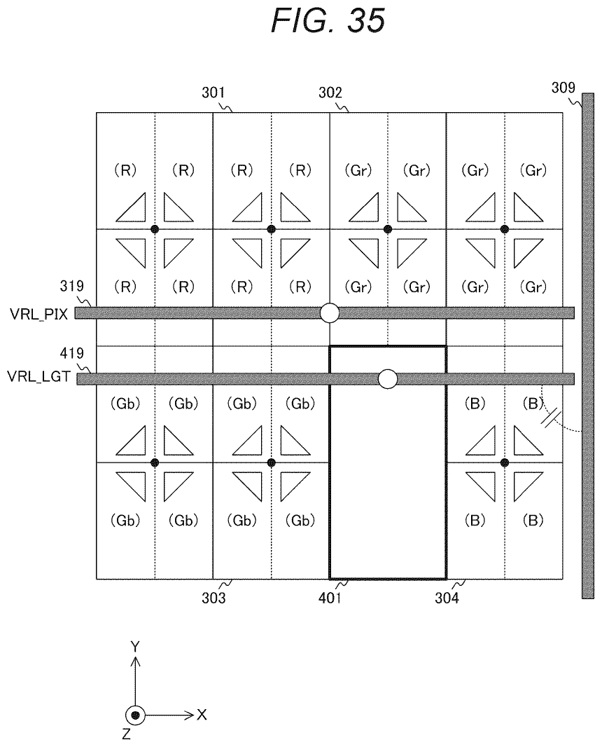

FIG. 35 is a plan view illustrating an example of a method of wiring the power supply lines 319 and 419 and a vertical signal line 309 according to the third embodiment of the present technology. The vertical signal line 309 is wired along the Y-axis direction, and the power supply line 319 of the negative voltage VRL_PIX and the power supply line 419 of the negative voltage VRL_LGT are wired along the X-axis direction. By setting the voltage of the power supply line 319 connected to the wells of the log transistors 421 and 422 to a negative voltage, the diffusion capacitance of the source portion of the log transistor 422 can be reduced.

Note that the first modification of the first embodiment in which a plurality of EVS pixels shares a current-voltage conversion unit or the like is applicable to the third embodiment.

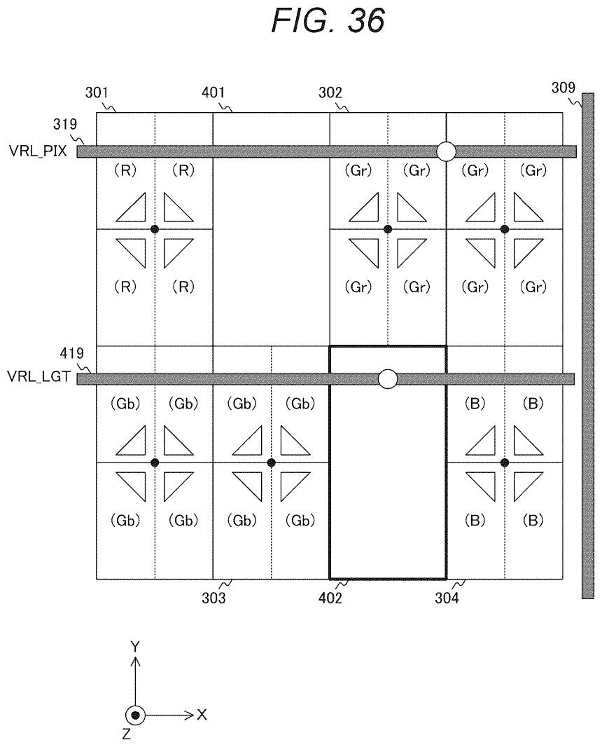

In this case, for example, as illustrated in FIG. 36, the power supply line 419 is connected to the EVS pixel 402.

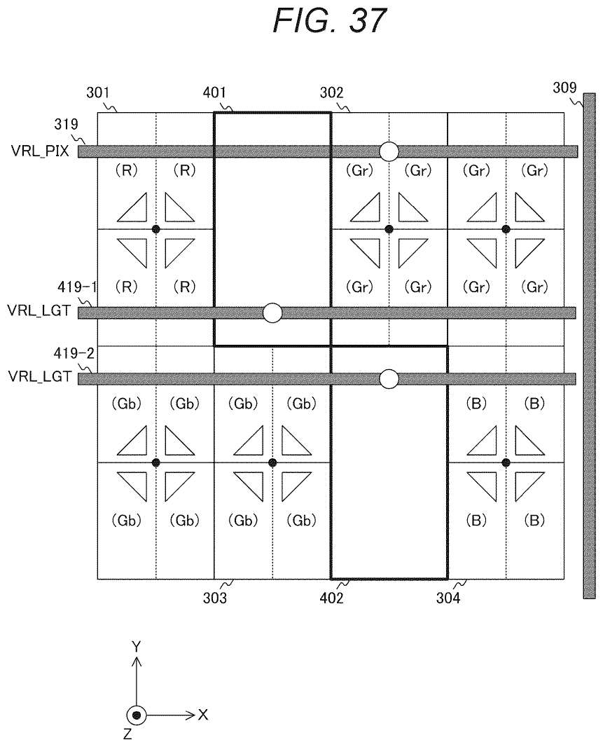

Alternatively, as illustrated in FIG. 37, power supply lines 419-1 and 419-2 are connected to EVS pixels 401 and 402.

Additionally, the second, third, fourth, and fifth modifications of the first embodiment are applicable to the third embodiment.

As described above, according to the third embodiment of the present technology, since the voltage of the power supply line 419 connected to the wells of the log transistors 421 and 422 is set to the negative voltage, it is possible to suppress the potential fluctuation as compared with a case where the voltage is set to the reference voltage.

### 4. Fourth Embodiment

In the first embodiment described above, an address event is detected for each EVS pixel 401, but binning of adding signals of a plurality of EVS pixels may be performed. A solid-state imaging element 200 of the fourth embodiment is different from that of the first embodiment in that a transistor for binning is further provided.

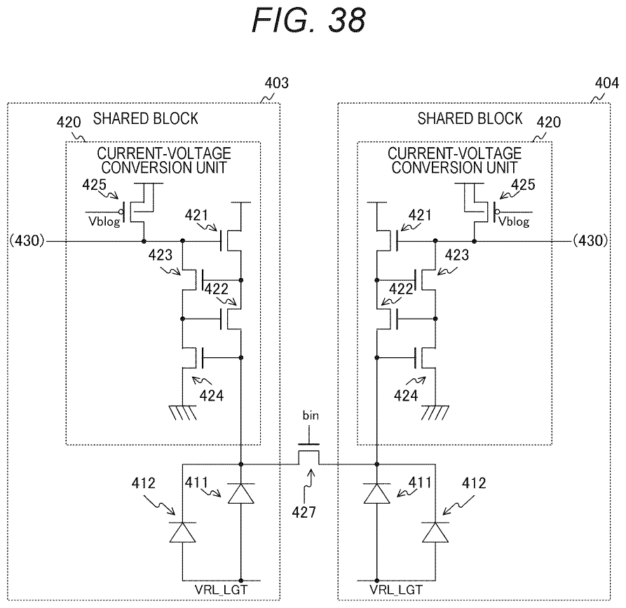

FIG. 38 is a circuit diagram illustrating a configuration example of shared blocks 403 and 404 according to the fourth embodiment of the present technology. In the fourth embodiment, the shared blocks 403 and 404 that share the circuit subsequent to a current-voltage conversion unit 420 by a plurality of EVS pixels are arranged. Furthermore, a binning transistor 427 is arranged therebetween. As the binning transistor 427, for example, an nMOS transistors is used.

The binning transistor 427 opens and closes a path between the input node of the current-voltage conversion unit 420 in the shared block 403 and the input node of the current-voltage conversion unit 420 in the shared block 404 according to a control signal bin from a vertical scanning circuit 220. The vertical scanning circuit 220 can cause binning to be executed by supplying a high-level control signal bin to close the binning transistor 427.

Furthermore, to the fourth embodiment, each of the first, second, third, fourth, and fifth modifications of the first embodiment, the second embodiment, and the third embodiment is applicable.

As described above, according to the fourth embodiment of the present technology, since the binning transistor 427 is added, binning can be performed.

### 5. Fifth Embodiment

In the first embodiment described above, the RDTI is formed in the grayscale pixel and the FTI is formed in the EVS pixel. However, the present invention is not limited to this configuration, and the RDTI may be formed in both the grayscale pixel and the EVS pixel. A solid-state imaging element 200 of a fifth embodiment is different from that of the first embodiment in that RDTI having different patterns are formed in a grayscale pixel and an EVS pixel.

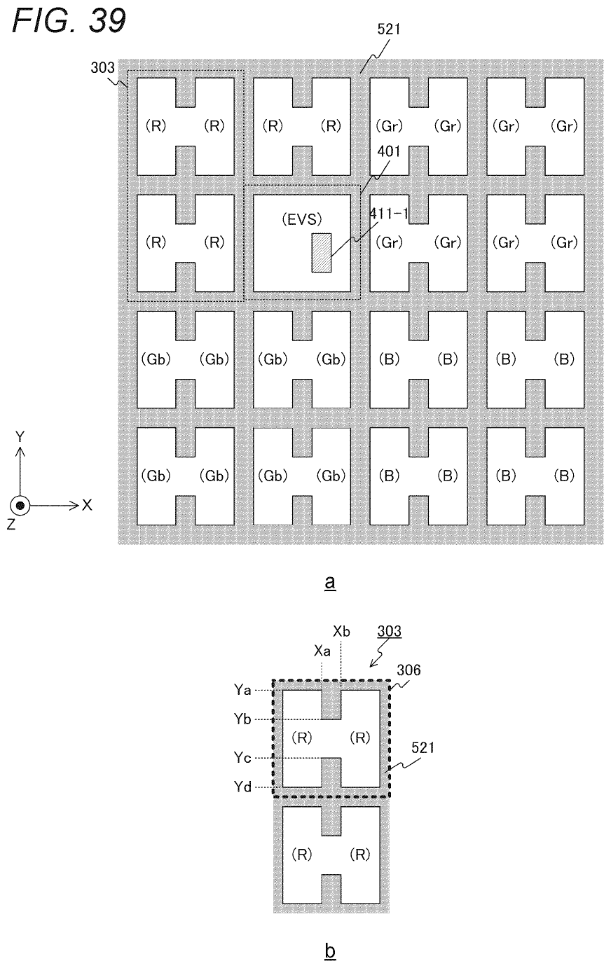

FIG. 39 is a plan view illustrating an example of an RDTI pattern according to the fifth embodiment of the present technology. In the drawing, a is a plan view illustrating an example of an RDTI pattern. In the drawing, b is a plan view illustrating an example of the RDTI pattern of a shared block 303 in a of the drawing.

As illustrated in a of the drawing, a plurality of grayscale pixels is arranged in the shared block 303, and an RDTI 521 is formed on the outer periphery of each grayscale pixel. In a of the drawing, a gray portion indicates the RDTI 521. Furthermore, the RDTI 521 is also formed on the outer periphery of an EVS pixel 401. Furthermore, a charge extraction port 411-1 is arranged in the EVS pixel 401. The charge extraction port 411-1 is connected to one end (cathode or the like) of a photoelectric conversion element 411 (not illustrated).

As illustrated in b of the drawing, four grayscale pixels are arranged in two rows ×two columns in the shared block 303. Of these four pixels, a region including two pixels arranged adjacent to each other in the X-axis direction is hereinafter referred to as a “unit region 306”. In the unit region 306, the RDTI 521 includes a rectangular region formed along the outer periphery of the region, and a protrusion protruding from the rectangular region to the center of the unit region 306. In b of the drawing, a region surrounded by the coordinates of (Xa, Ya), (Xb, Ya), (Xa, Yb), and (Xb, Yb) and a region surrounded by the coordinates of (Xa, Yc), (Xb, Yc), (Xa, Yd), and (Xb, Yd) correspond to the protrusion.

The EVS pixel 401 has the same area as the unit region 306. Furthermore, the RDTI 521 of the EVS pixel 401 has no protrusion, and the EVS pixel 401 is not divided by the RDTI 521. As described above, the RDTI pattern of the EVS pixel 401 is different from the RDTI pattern of the unit region 306.

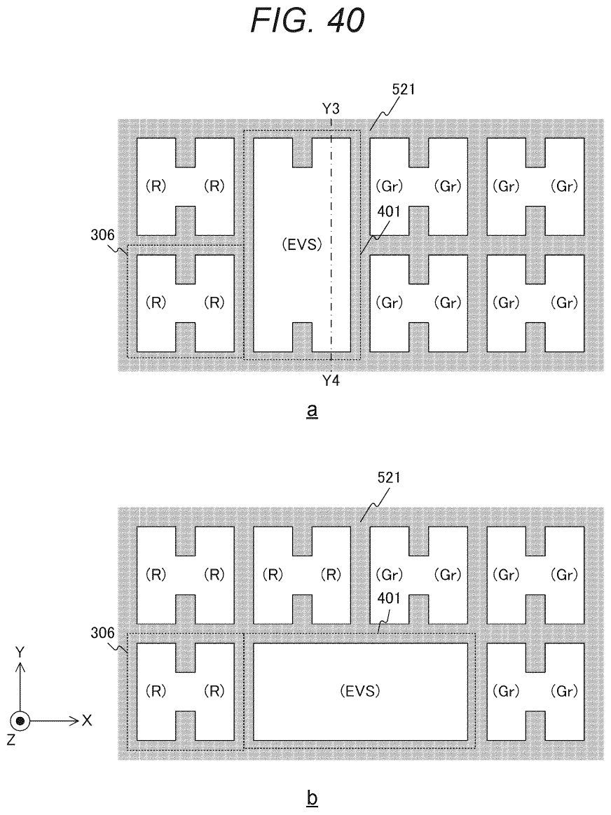

Note that as illustrated in a and b of FIG. 40, the area of the EVS pixel 401 as viewed from the Z-axis direction may be the same as that of two unit regions. In this case, the EVS pixel 401 may be enlarged in the Y-axis direction as illustrated in a of the drawing, or may be enlarged in the Z-axis direction as illustrated in b of the drawing.

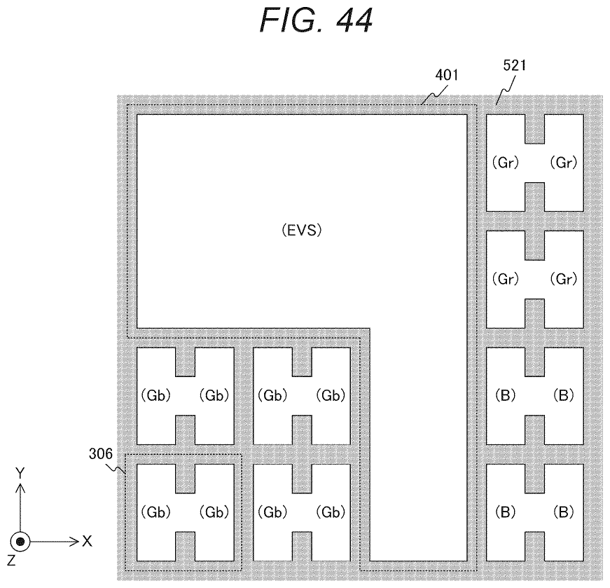

Furthermore, the RDTI 521 of the EVS pixel 401 may have a protrusion as illustrated in a of the drawing, or may not have a protrusion as illustrated in b of the drawing. In a case where the RDTI 521 of the EVS pixel 401 has a protrusion, it is possible to ensure pattern symmetry with the RDTI 521 of the grayscale pixel. Note, however, that depending on the position of the charge extraction port 411-1 (not illustrated), the protrusion may hinder the transfer of charge, and in that case, it is preferable not to provide the protrusion. Similarly, in FIGS. 44 to 49, the presence or absence of the protrusion of the EVS pixel 401 is optional.

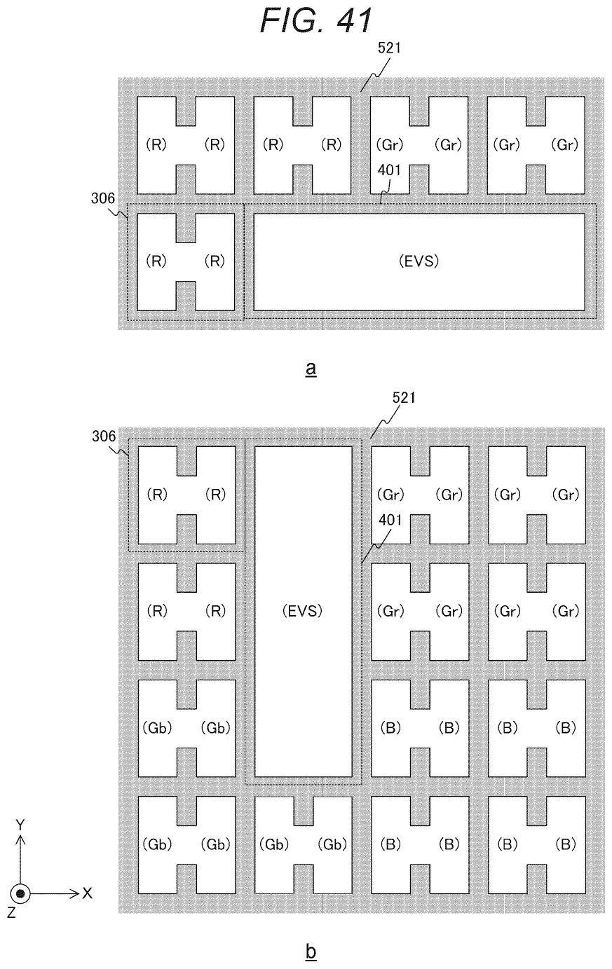

Furthermore, as illustrated in a and b of FIG. 41, the area of the EVS pixel 401 as viewed from the Z-axis direction may be the same as that of three unit regions. In this case, the EVS pixel 401 may be enlarged in the X-axis direction as illustrated in a of the drawing, or may be enlarged in the Y-axis direction as illustrated in b of the drawing.

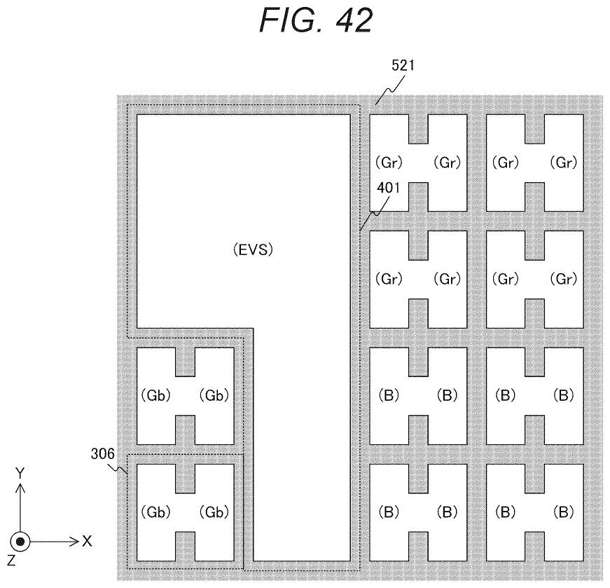

Alternatively, as illustrated in FIG. 42, the EVS pixel 401 may be enlarged in the X-axis direction and the Y-axis direction, and the area thereof may be the same as that of six unit regions.

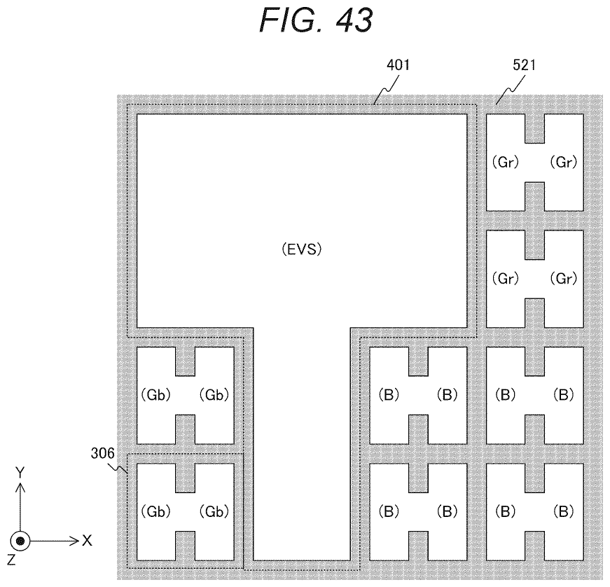

Alternatively, as illustrated in FIG. 43, the EVS pixel 401 may be enlarged in the X-axis direction and the Y-axis direction, and the area thereof may be the same as that of eight unit regions.

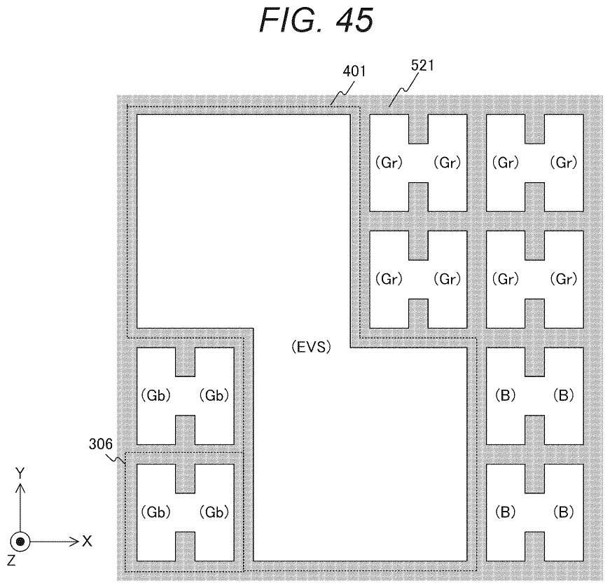

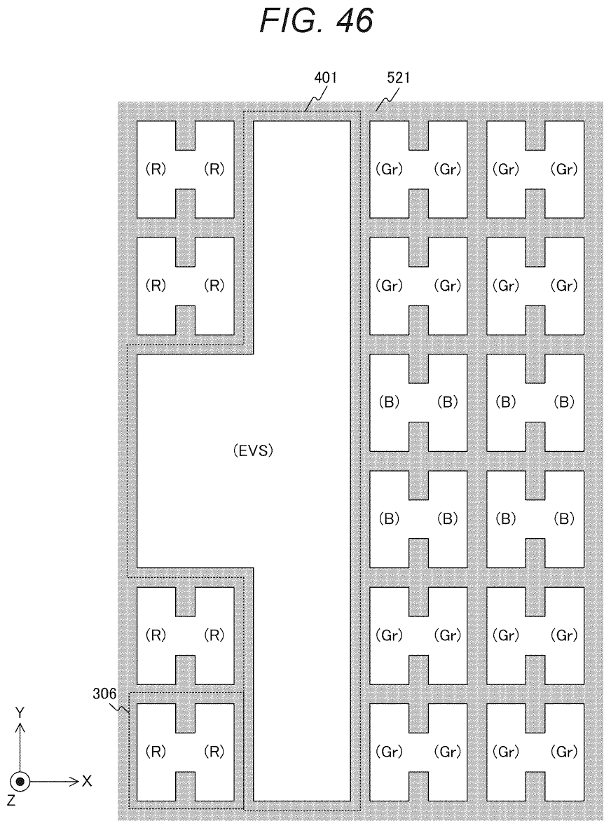

When the area of the EVS pixel 401 is enlarged to eight unit regions, the shape thereof is not limited to that illustrated in FIG. 43. The shape of the EVS pixel 401 may be the one illustrated in FIG. 44, FIG. 45, or FIG. 46.

In FIGS. 39 to 46 described above, a pixel region in which grayscale pixels are arranged and having the same area as the EVS pixel 401 is assumed as a pattern comparison target. The RDTI 521 of the EVS pixel 401 is reduced as compared to the pixel region of the same area.

Note that the RDTI 521 is an example of a TI described in the claims.

Here, a configuration in which a pixel region in which grayscale pixels are arranged and having the same area as the EVS pixel 401 and the EVS pixel 401 have the same RDTI pattern is assumed as a comparative example.

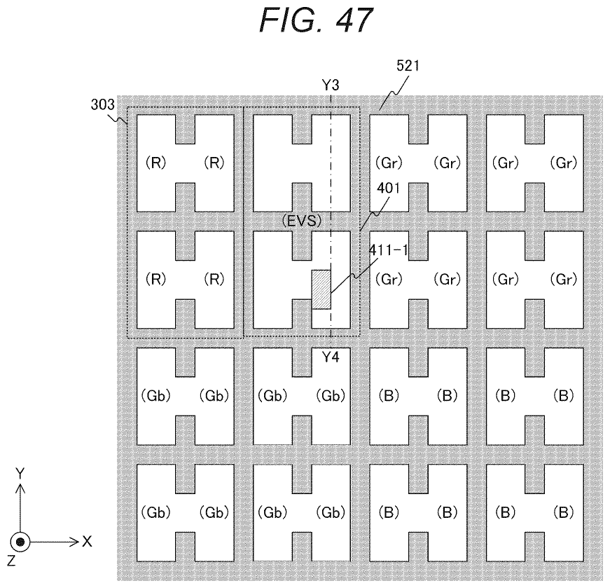

FIG. 47 is a plan view illustrating an example of an RDTI pattern of a comparative example. In this comparative example, the area of the EVS pixel 401 is the same as that of two unit regions, and the EVS pixel 401 is divided into two regions by the RDTI 521.

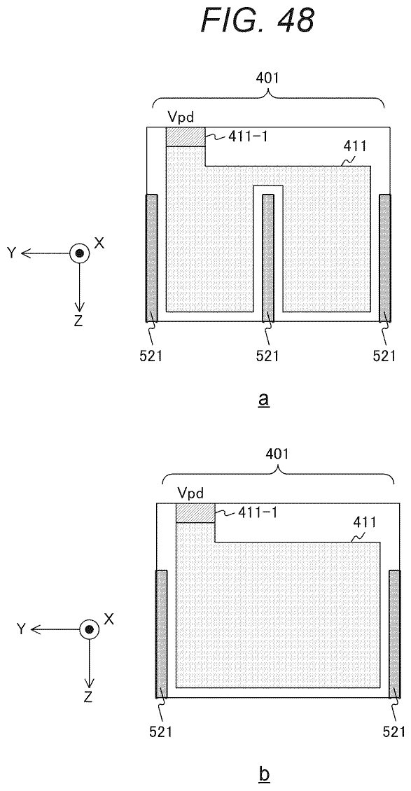

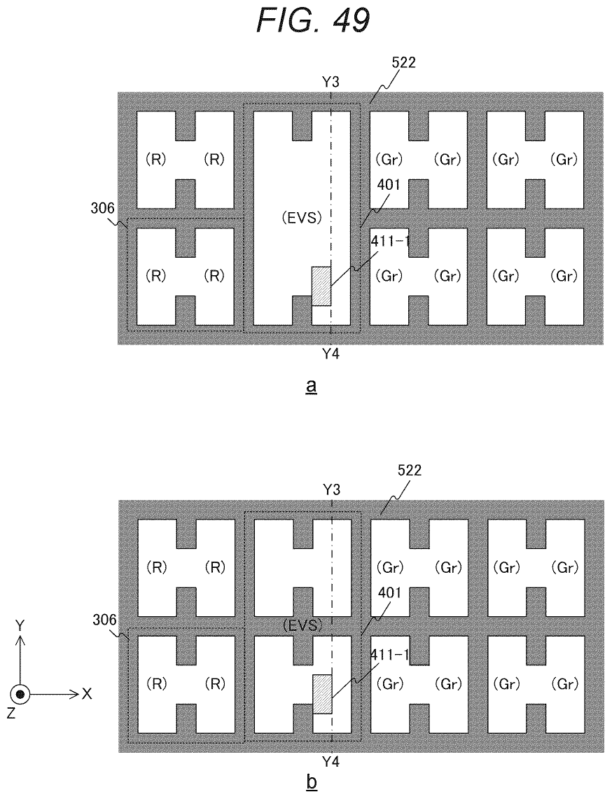

FIG. 48 is an example of a cross-sectional view of the EVS pixels of the comparative example and the fifth embodiment of the present technology. In FIG. 48, a is a cross-sectional view taken along a line segment Y3-Y4 of FIG. 47 and viewed from the X-axis direction. In FIG. 48, b is a cross-sectional view taken along a line segment Y3-Y4 of a of FIG. 40 and viewed from the X-axis direction.

As illustrated in a of FIG. 48, in the comparative example, the charge transfer path to the charge extraction port 411-1 straddles the central RDTI 521, and the RDTI 521 serves as a barrier. In this case, variations in the characteristics of the EVS 401 may occur due to variations in the RDTI 521.

On the other hand, as illustrated in b of FIG. 48, in a case where the pattern is changed so that the RDTI 521 does not divide the EVS pixel 401, it is possible to suppress the characteristic variation of the EVS pixel 401 due to the variation of the RDTI 521. As a result, the signal quality is improved.

Note that the second to fifth modifications of the first embodiment and the second, third, and fourth embodiments are applicable to the fifth embodiment.

As described above, according to the fifth embodiment of the present technology, since the RDTI pattern of the EVS pixel 401 is different from that of the grayscale pixel, characteristic variation of the EVS pixel 401 due to variation of the RDTI 521 can be suppressed, and signal quality is improved.

### First Modification

In the above-described fifth embodiment, the RDTI 521 is formed in each of the pixels, but the FTI 522 may be formed instead of the RDTI 521. A solid-state imaging element 200 of a first modification of the fifth embodiment is different from that of the fifth embodiment in that an FTI 522 is formed instead of an RDTI 521.

In FIG. 49, a and b are plan views illustrating examples of FTI patterns of the first modification of the fifth embodiment of the present technology and the comparative example. In the drawing, a is a plan view illustrating an example of an FTI pattern of the first modification of the fifth embodiment. In the drawing, b is a plan view illustrating an example of an FTI pattern of the comparative example.

As illustrated in a of the drawing, the FTI 522 is formed instead of the RDTI 521 for each pixel. The FTI pattern is the same as the RDTI pattern of the fifth embodiment. As illustrated in b of the drawing, in the comparative example, the EVS pixel 401 is divided by the FTI 522. Note that the FTI 522 is an example of a TI described in the claims.

Note that the shape of the EVS pixel 401 is not limited to that exemplified in a of the drawing. The shapes illustrated in a of FIG. 42, b of FIG. 40, and FIGS. 41 to 46 are applicable to the first modification of the fifth embodiment.

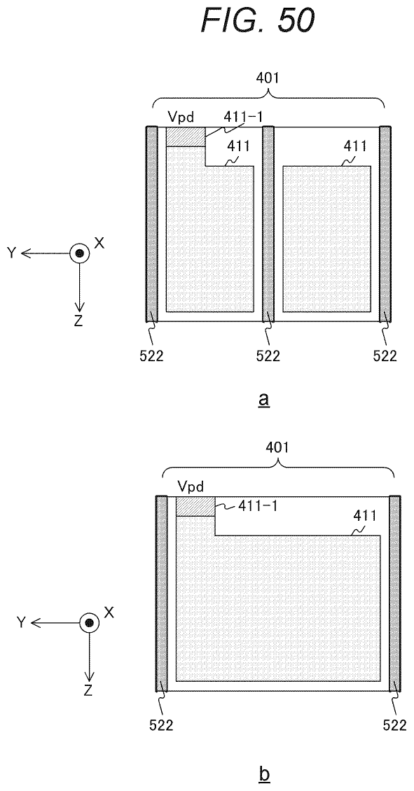

In FIG. 50, a and b are examples of cross-sectional views of the EVS pixel 401 of the comparative example and the first modification of the fifth embodiment of the present technology. In FIG. 50, a is a cross-sectional view taken along a line segment Y3-Y4 of b of FIG. 49 and viewed from the X-axis direction. In FIG. 50, b is a cross-sectional view taken along a line segment Y3-Y4 of a of FIG. 49 and viewed from the X-axis direction.

As illustrated in a of FIG. 50, in the comparative example, a charge transfer path to a charge extraction port 411-1 straddles the central FTI 522, and there is a possibility that variations occur in the characteristics of the EVS 401 due to the variations.

On the other hand, as illustrated in b of FIG. 50, in a case where the pattern is changed so that the FTI 522 does not divide the EVS pixel 401, it is possible to suppress the characteristic variation of the EVS pixel 401 due to the variation of the FTI 522.

As described above, according to the first modification of the fifth embodiment of the present technology, since the FDTI pattern of the EVS pixel 401 is different from that of the grayscale pixel, characteristic variation of the EVS pixel 401 due to variation of the FDTI 522 can be suppressed.

### Second Modification

In the fifth embodiment described above, a detection circuit such as the current-voltage conversion unit 420 is provided for each EVS pixel, but with this configuration, it is difficult to miniaturize the EVS pixel. A solid-state imaging element 200 of a second modification of the fifth embodiment is different from that of the fifth embodiment in that a plurality of EVS pixels shares a circuit subsequent to a current-voltage conversion unit 420.

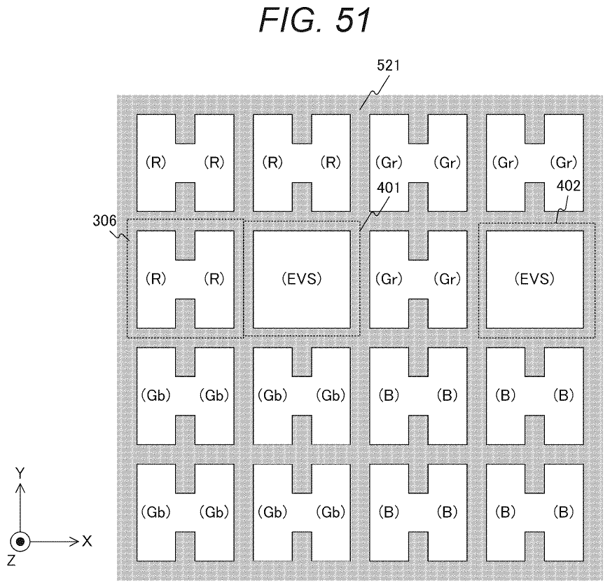

FIGS. 51 to 58 are plan views illustrating examples of layouts of EVS pixels 401 and 402 and RDTI patterns according to the second modification of the fifth embodiment. In these plan views, the EVS pixels 401 and 402 illustrate EVS pixels in a shared block 403 illustrated in FIG. 17. Note that the EVS pixels 401 and 402 are examples of first and second detection pixels described in the claims.

As illustrated in FIG. 51, the EVS pixels 401 and 402 may be arranged in the X-axis direction without being adjacent to each other.

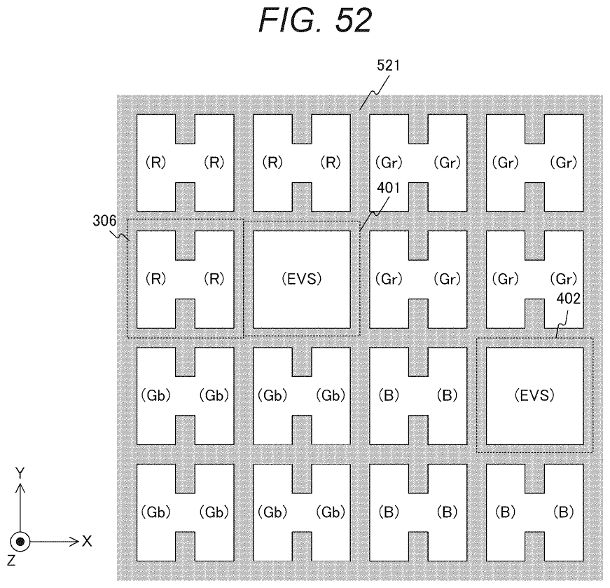

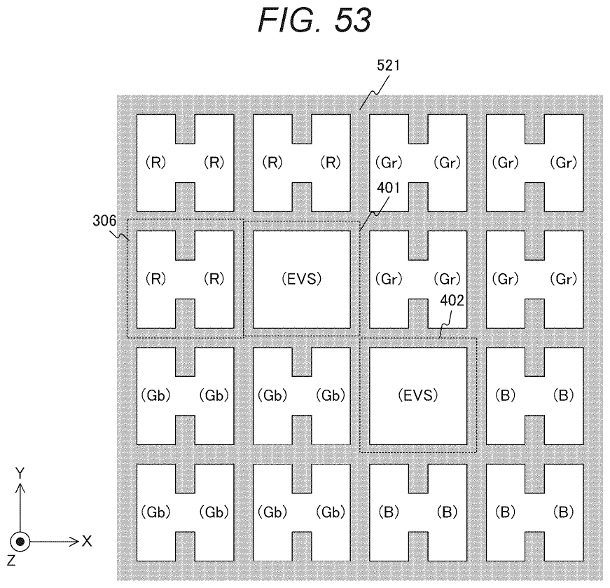

Furthermore, as illustrated in FIGS. 52 and 53, the EVS pixels 401 and 402 can be arranged in an oblique direction. In FIG. 52, the EVS pixels 401 and 402 are arranged in a non-adjacent manner, and in FIG. 53, the EVS pixels 401 and 402 are arranged in an adjacent manner.

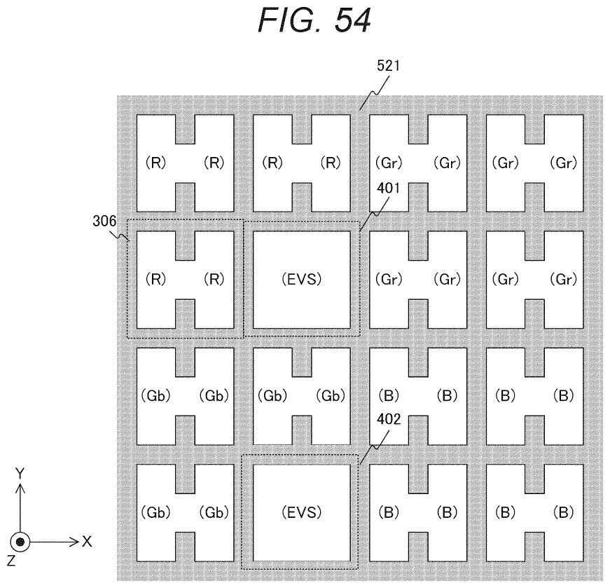

Furthermore, as illustrated in FIG. 54, the EVS pixels 401 and 402 can be arranged in the Y-axis direction without being adjacent to each other.

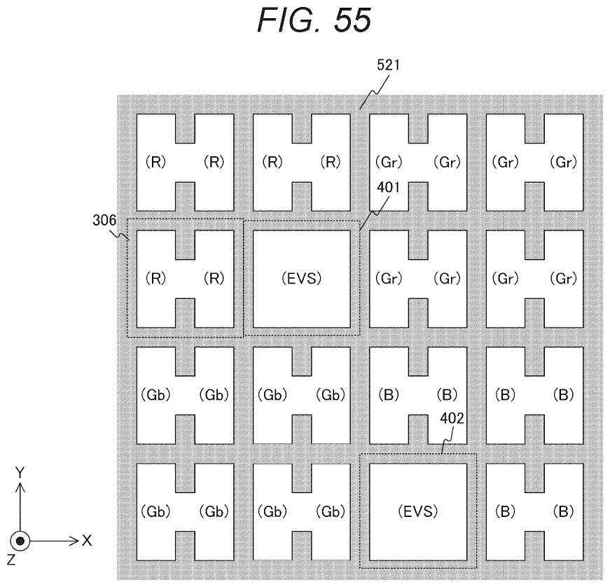

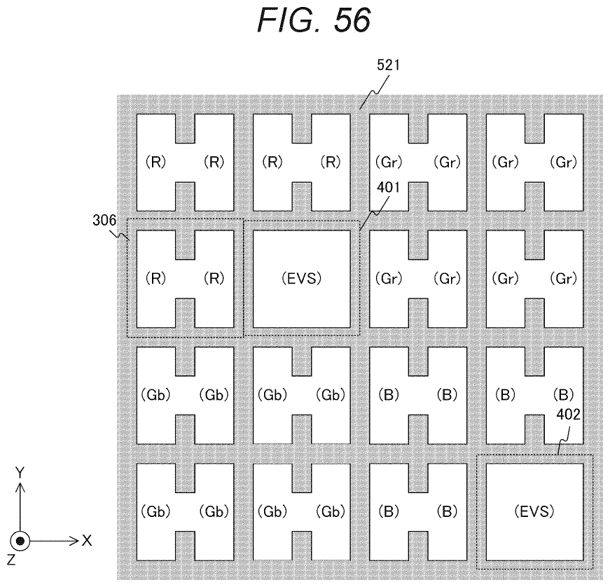

Furthermore, as illustrated in FIGS. 55 and 56, the EVS pixels 401 and 402 can be arranged in an oblique direction without being adjacent to each other.

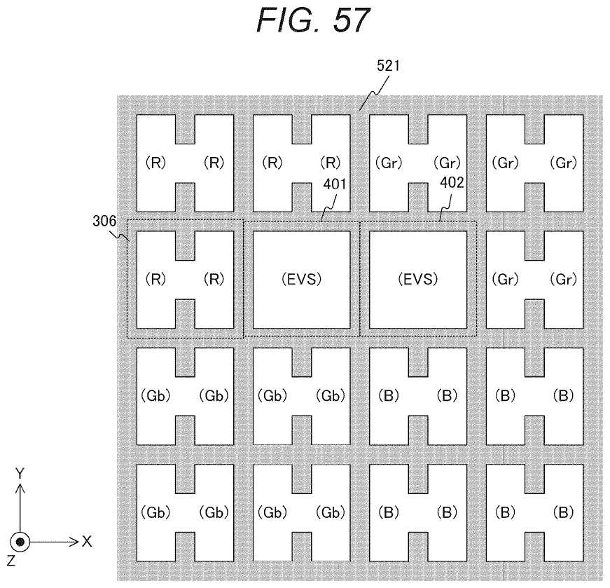

Furthermore, as illustrated in FIG. 57, the EVS pixels 401 and 402 can be arranged adjacent to each other in the X-axis direction.

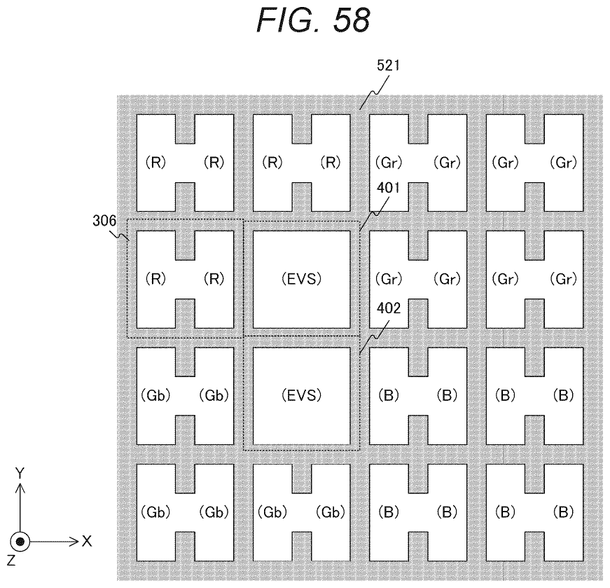

Alternatively, as illustrated in FIG. 58, the EVS pixels 401 and 402 may be arranged adjacent to each other in the Y-axis direction.

Also in each of FIGS. 51 to 58, similarly to the fifth embodiment, the RDTI pattern of the EVS pixel 401 is different from that of the grayscale pixel.

As described above, according to the second modification of the fifth embodiment of the present technology, since the plurality of EVS pixels shares the circuit subsequent to the current-voltage conversion unit 420, miniaturization of the pixels is facilitated.

### 6. Sixth Embodiment

In the first embodiment described above, the areas of the photoelectric conversion elements of the plurality of grayscale pixels are the same. However, embedding the EVS pixel may cause a difference between the resist opening shape of the grayscale pixel adjacent to the EVS pixel and the resist opening shape of the grayscale pixel not adjacent to the EVS pixel. As a result, a difference occurs in pixel characteristics between the grayscale pixel adjacent to the EVS pixel and the grayscale pixel not adjacent to the EVS pixel, and the image quality of the image data may be deteriorated due to the difference. A solid-state imaging element 200 of a sixth embodiment is different from that of the first embodiment in that the area of the photoelectric conversion element of the grayscale pixel adjacent to the EVS pixel is different from that of the grayscale pixel not adjacent to the EVS pixel.

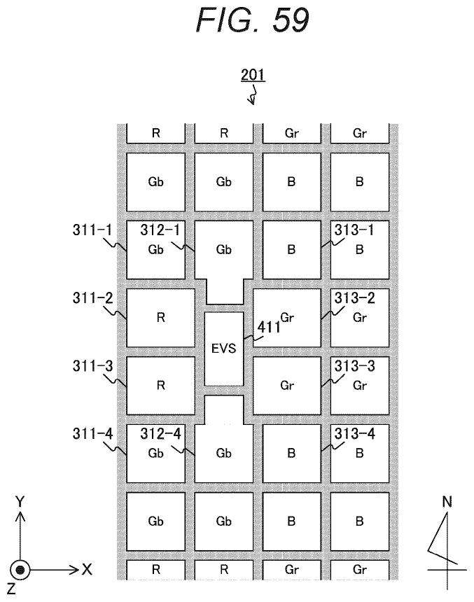

FIG. 59 is an example of a plan view of a pixel chip in a case where the sizes of EVS pixels in the row direction and the column direction are reduced according to the sixth embodiment of the present technology. As described above, a predetermined number of grayscale pixels and a predetermined number of EVS pixels are arranged in a two-dimensional lattice pattern on a light receiving surface of a pixel chip 201. Each of these pixels includes a photoelectric conversion element. A photoelectric conversion element 411 in the drawing is a photoelectric conversion element in the EVS pixel. Furthermore, regions denoted by “R” and “B” indicate photoelectric conversion elements in grayscale pixels (i.e., the R pixel and the B pixel) that receive red and blue incident light. Regions denoted by “Gr” and “Gb” indicate photoelectric conversion elements in grayscale pixels (i.e., the Gr pixel and the Gb pixel) that receive green incident light.

Furthermore, for convenience of description, upward, downward, leftward, and rightward directions in the sheet are defined as north, south, west, and east directions. This similarly applies hereinafter. The X-axis direction (in other words, the row direction) corresponds to the east-west direction, and the Y-axis direction (in other words, the column direction) corresponds to the north-south direction. The Z-axis direction corresponds to the optical axis direction.

For example, in the quad Bayer array, it is assumed that two pixels arranged in the column direction among four R pixels of two rows×two columns are replaced with EVS pixels. There are 10 grayscale pixels adjacent to the EVS pixel. The photoelectric conversion elements of the 10 pixels are 311-1, 311-2, 311-3, 311-4, 312-1, 312-4, 313-1, 313-2, 313-3, and 313-4.

The photoelectric conversion element 311-1 is arranged in the northwest direction of the photoelectric conversion element 411 of the EVS pixel, the photoelectric conversion element 312-1 is arranged in the north direction of the photoelectric conversion element 411, and the photoelectric conversion element 313-1 is arranged in the northeast direction of the photoelectric conversion element 411. In addition, although the EVS pixels extend over two rows, the photoelectric conversion elements 311-2 and 313-2 are arranged in a row on the north side and the photoelectric conversion elements 311-3 and 313-3 are arranged in a row on the south side among these two rows. The photoelectric conversion element 311-4 is arranged in the southwest direction of the photoelectric conversion element 411, the photoelectric conversion element 312-4 is arranged in the south direction of the photoelectric conversion element 411, and the photoelectric conversion element 313-4 is arranged in the southeast direction of the photoelectric conversion element 411.

In the drawing, the size in the row direction and the column direction of the EVS pixel is reduced as compared with the grayscale pixel. As a result, the area of the photoelectric conversion element of the grayscale pixel adjacent to the EVS pixel is enlarged as compared with the area of the grayscale pixel not adjacent to the EVS pixel. In the drawing, the areas of the photoelectric conversion elements 312-1, 311-2, 313-2, 311-3, 313-3, and 312-4 are enlarged.

Whether to enlarge or reduce the grayscale pixel and the position of the grayscale pixel to be enlarged or reduced can be appropriately set according to the correction content of the pixel characteristic.

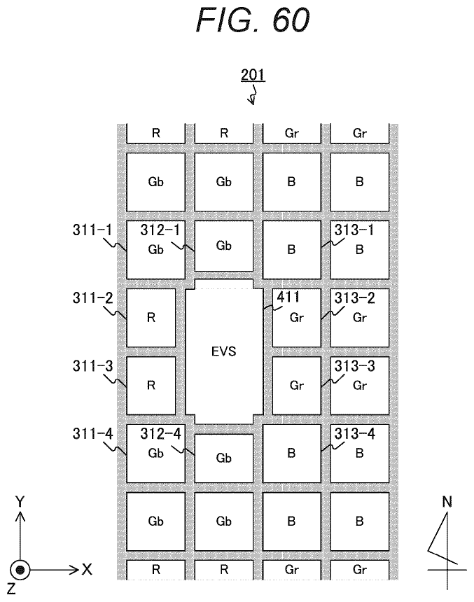

For example, as illustrated in FIG. 60, the sizes of the EVS pixels in the row direction and the column direction can be enlarged. In this case, the area of the photoelectric conversion element of the grayscale pixel adjacent to the EVS pixel is reduced as compared with the area of the grayscale pixel not adjacent to the EVS pixel. In the drawing, the areas of the photoelectric conversion elements 312-1, 311-2, 313-2, 311-3, 313-3, and 312-4 are reduced.

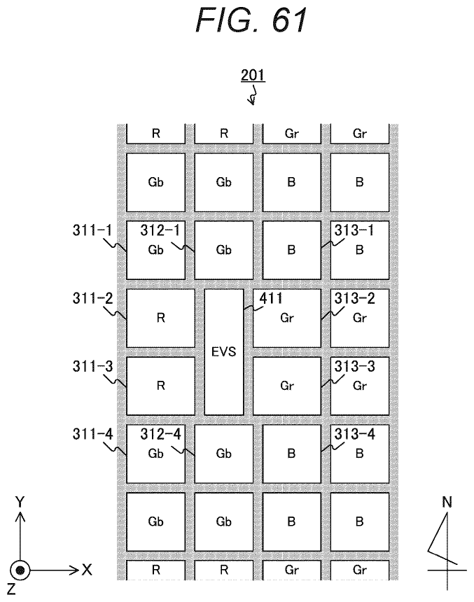

Furthermore, as illustrated in FIG. 61, the size in the row direction of the EVS pixel can be reduced, and the size in the column direction of the EVS pixel can be made the same as that of the grayscale pixel. In this case, the areas of the photoelectric conversion elements 311-2, 313-2, 311-3, and 313-3 are enlarged.

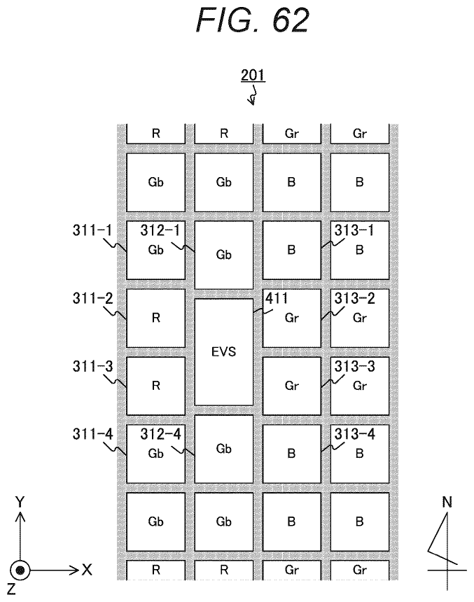

Furthermore, as illustrated in FIG. 62, the size in the row direction of the EVS pixel can be made the same as that of the grayscale pixel, and the size in the column direction of the EVS pixel can be reduced. In this case, the areas of the photoelectric conversion elements 312-1 and 312-4 are enlarged.

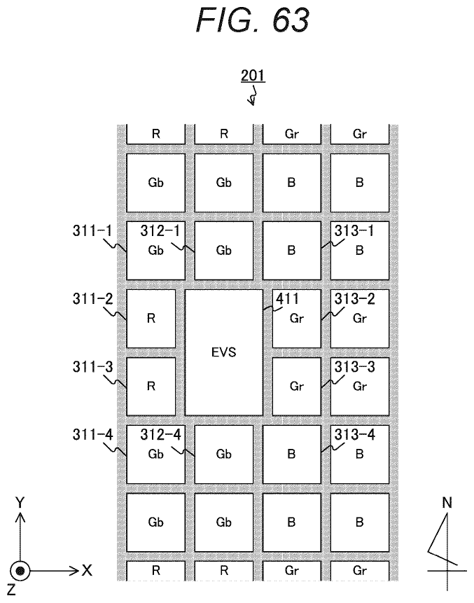

Furthermore, as illustrated in FIG. 63, the size in the row direction of the EVS pixel can be enlarged, and the size in the column direction of the EVS pixel can be made the same as that of the grayscale pixel. In this case, the areas of the photoelectric conversion elements 311-2, 313-2, 311-3, and 313-3 are reduced.

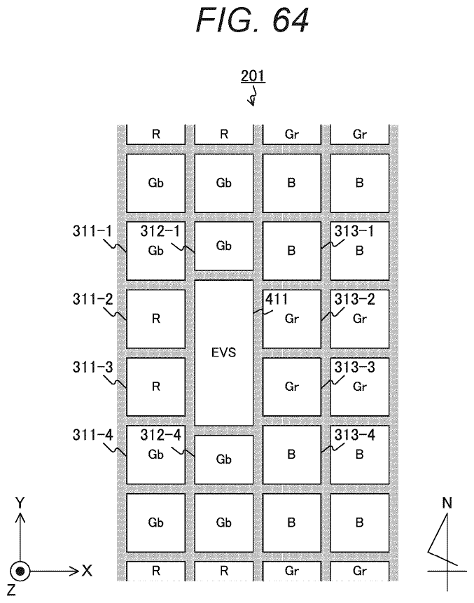

Furthermore, as illustrated in FIG. 64, the size in the row direction of the EVS pixel can be made the same as that of the grayscale pixel, and the size in the column direction of the EVS pixel can be enlarged. In this case, the areas of the photoelectric conversion elements 312-1 and 312-4 are reduced.

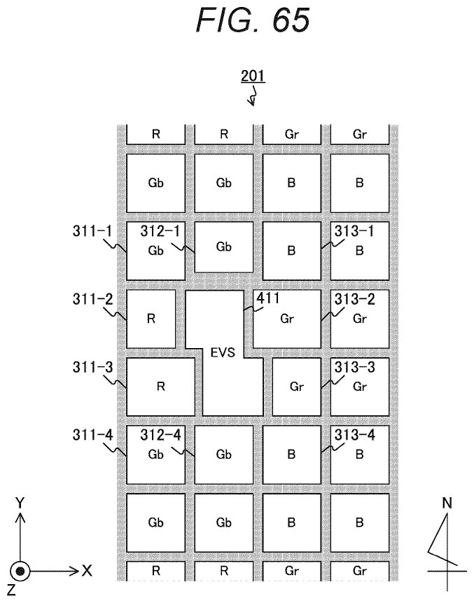

Furthermore, as illustrated in FIGS. 65, 66, and 67, the shapes of the photoelectric conversion elements of a pair of grayscale pixels adjacent to the EVS pixel and arranged in the same row or column can be made asymmetric.

In FIG. 65, the EVS pixel extends over two rows, and among the two rows, the EVS pixel expands to the west in the north row and the EVS pixel expands to the east in the south row. In this case, while the area of the photoelectric conversion element 311-2 is reduced, the area of the photoelectric conversion element 313-2 in the same row is enlarged. In addition, while the area of the photoelectric conversion element 311-3 is enlarged, the area of the photoelectric conversion element 313-3 in the same row is reduced. Focusing on the column direction, while the area of the photoelectric conversion element 311-2 is reduced, the area of the photoelectric conversion element 311-3 in the same column is enlarged. In addition, while the area of the photoelectric conversion element 313-2 is enlarged, the area of the photoelectric conversion element 313-3 in the same column is reduced. Therefore, the shapes of the photoelectric conversion elements become asymmetric.

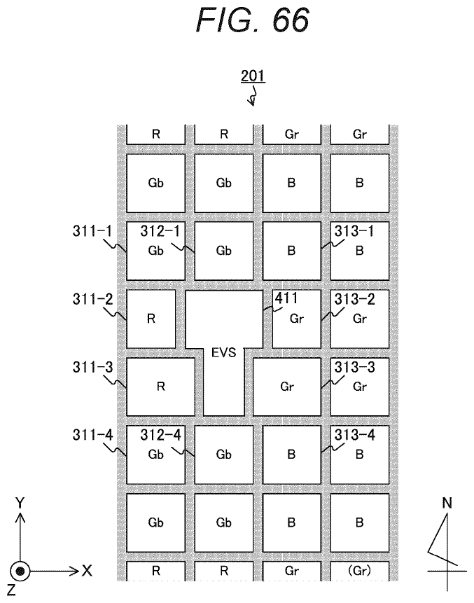

In FIG. 66, the EVS pixel extends over two rows, and among the two rows, the EVS pixel is enlarged in the north row and the EVS pixel is reduced in the south row. In this case, while the area of the photoelectric conversion element 311-2 is reduced, the area of the photoelectric conversion element 311-3 in the same column is enlarged. In addition, while the area of the photoelectric conversion element 313-2 is reduced, the area of the photoelectric conversion element 313-3 in the same column is enlarged. Therefore, the shapes of the photoelectric conversion elements become asymmetric.

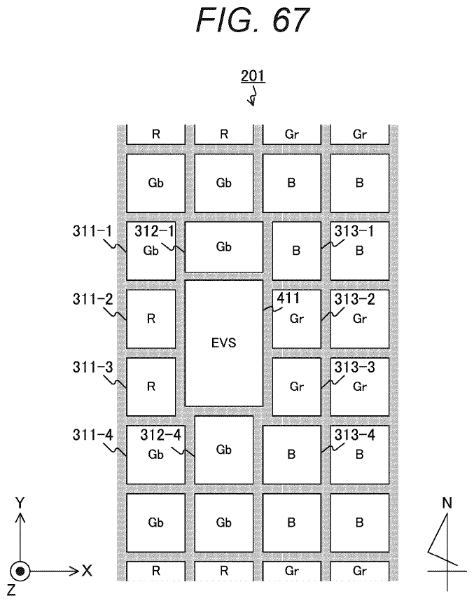

In FIG. 67, the EVS pixel is enlarged in the east-west direction on the north side and is reduced on the south side. In this case, while the photoelectric conversion element 312-1 is enlarged in the row direction and is reduced in the column direction, the photoelectric conversion element 312-4 in the same column is reduced in the row direction and is enlarged in the column direction. In addition, the photoelectric conversion element 311-4 is enlarged as compared with the photoelectric conversion elements 311-1, 311-2, and 311-3 of the same column. The photoelectric conversion element 313-4 is enlarged as compared with the photoelectric conversion elements 313-1, 313-2, and 313-3 of the same column. Therefore, the shapes of the photoelectric conversion elements become asymmetric.

Note that the grayscale pixels and the EVS pixel are mixed, but the present invention is not limited to this configuration. For example, instead of the EVS pixel, a time of flight (ToF) pixel for performing distance measurement by the ToF method can be arranged. This similarly applies to the first to fifth embodiments described above.

In summary, on the light receiving surface of the pixel chip 201, the area of the photoelectric conversion element of the grayscale pixel adjacent to the non-grayscale pixel is different from the area of the photoelectric conversion element of the grayscale pixel not adjacent to the non-grayscale pixel. As a result, it is possible to reduce the difference in pixel characteristics between the grayscale pixel adjacent to the non-grayscale pixel and the grayscale pixel not adjacent to the non-grayscale pixel, which is caused by embedding of the non-grayscale pixel, and to improve the image quality of the image data.

Furthermore, as the non-grayscale pixel, for example, an EVS pixel is used.

Furthermore, the area of the photoelectric conversion element of the grayscale pixel adjacent to the EVS pixel and arranged in the same row or column as the EVS pixel is different from the area of the photoelectric conversion element of the grayscale pixel not adjacent to the non-grayscale pixel. For example, in FIG. 59, among the adjacent 10 pixels, the areas of the photoelectric conversion elements 312-1, 311-2, 313-2, 311-3, 313-3, and 312-4 in the same row or column as the EVS pixel are enlarged.

Furthermore, the shapes of the photoelectric conversion elements of a pair of grayscale pixels adjacent to the EVS pixel and arranged in the same row or column are asymmetric. For example, in FIG. 65, the shapes of the photoelectric conversion elements 311-2 and 313-2 in the same row are asymmetric.

Note that each of the first to fifth embodiments is applicable to the sixth embodiment.

As described above, according to the sixth embodiment of the present technology, since the area of the photoelectric conversion element of the grayscale pixel adjacent to the EVS pixel is different from the area of the photoelectric conversion element of the grayscale pixel not adjacent to the EVS pixel, the difference in pixel characteristics can be reduced.

### 7. Example of Application to Mobile Body

The technology (the present technology) according to the present disclosure is applicable to various products. For example, the technology according to the present disclosure may also be implemented as a device mounted on any type of mobile body such as an automobile, an electric automobile, a hybrid electric automobile, a motorcycle, a bicycle, a personal mobility, an airplane, a drone, a ship, and a robot.

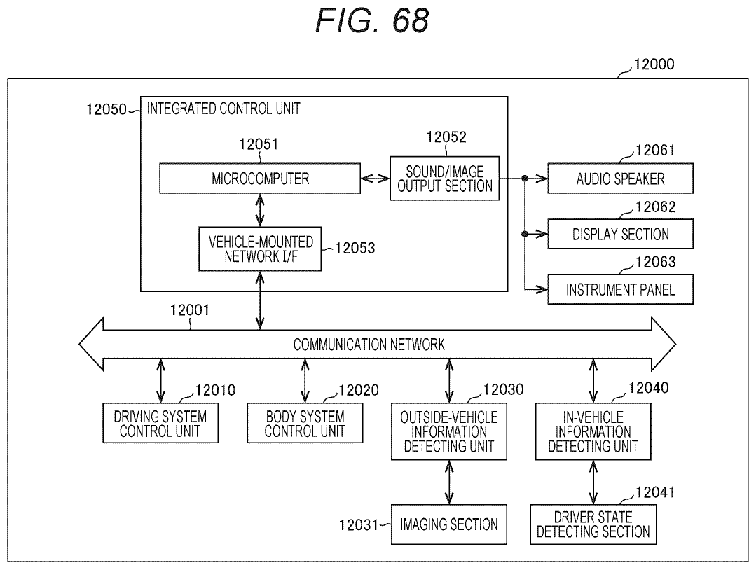

FIG. 68 is a block diagram illustrating a schematic configuration example of a vehicle control system as an example of a mobile body control system to which the technology of the present disclosure is applied.

The vehicle control system 12000 includes a plurality of electronic control units connected to each other via a communication network 12001. In the example illustrated in FIG. 68, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 68, an audio speaker 12061, a display section 12062, and an instrument panel 12063 are illustrated as the output device. The display section 12062 may, for example, include at least one of an on-board display and a head-up display.

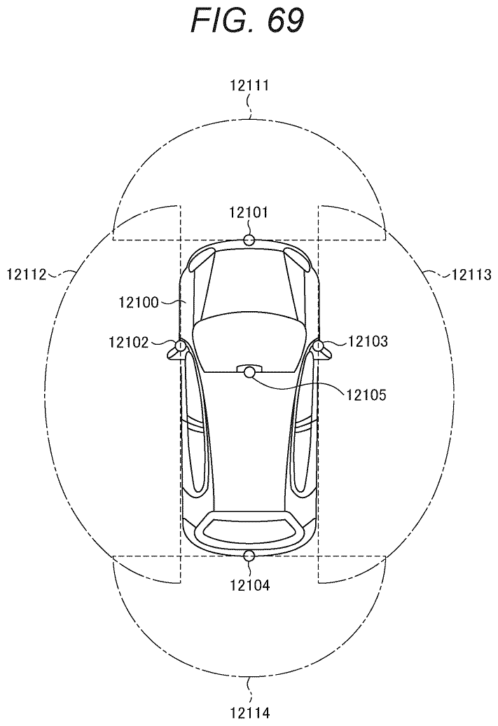

FIG. 69 is a diagram illustrating an example of an installation position of the imaging section 12031.

In FIG. 69, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 69 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied, for example, to the imaging section 12031 among the configurations described above. Specifically, the imaging device 100 in FIG. 1 can be applied to the imaging section 12031. By applying the technology according to the present disclosure to the imaging section 12031, it is possible to improve the performance of the system by increasing the detection accuracy of the address event.

Note that the embodiments described above indicate examples for embodying the present technology, and the matters in the embodiments and the matters specifying the invention in the claims have correspondence relationships. Similarly, the matters specifying the invention in the claims and matters with the same names in the embodiments of the present technology have correspondence relationships. Note, however, that the present technology is not limited to the embodiments, and can be embodied by making various modifications to the embodiments without departing from the gist thereof.

Furthermore, the procedures described in the above-described embodiments may be considered as a method including a series of procedures, and may be considered as a program for allowing a computer to execute the series of procedures and a recording medium that stores the program. As this recording medium, for example, a compact disc (CD), a MiniDisc (MD), a digital versatile disc (DVD), a memory card, a Blu-ray (registered trademark) disc, and the like can be used.

Note that the effect described in the present specification is illustrative only and is not limitative; there may also be other effects.

Note that the present technology may also have the following configurations.

(1) A solid-state imaging element including
a pixel region in which a predetermined number of grayscale pixels for generating a grayscale signal according to an amount of charge generated by photoelectric conversion are arranged, and
a non-grayscale pixel not corresponding to the grayscale pixel and in which a TI having a pattern different from that of the pixel region is formed.

(2) The solid-state imaging element according to (1), in which
the non-grayscale pixel includes a detection pixel that detects, as an address event, that an amount of change in a photocurrent generated by photoelectric conversion exceeds a predetermined threshold.

(3) The solid-state imaging element according to (2), in which
the TI includes an FTI, and
the FTI insulates a grayscale-side well that is a well of the grayscale pixel and a detection-side well that is a well of the detection pixel.

(4) The solid-state imaging element according to (3), in which:
the detection pixel includes a photoelectric conversion element and a current-voltage conversion unit;
the current-voltage conversion unit includes a predetermined number of log transistors that convert the photocurrent into a logarithmic voltage, and a predetermined number of transimpedance amplifiers that invert and amplify the logarithmic voltage; and
the FTI is formed on an outer periphery of the detection pixel when viewed from an optical axis direction.

(5) The solid-state imaging element according to (4), in which
the log transistor is arranged in the detection pixel when viewed from an optical axis direction.

(6) The solid-state imaging element according to (4), in which
the log transistor and the transimpedance amplifier are arranged in the detection pixel when viewed from an optical axis direction.

(7) The solid-state imaging element according to (4), in

which
the FTI is formed on an outer periphery of a region in which a pair of grayscale pixels are arranged, an outer periphery of a region in which the log transistor is arranged, and an outer periphery of a region in which the transimpedance amplifier is arranged.

(8) The solid-state imaging element according to any one of (4) to (7), in which
at least one of the predetermined number of log transistors is diode-connected.

(9) The solid-state imaging element according to (3), in which
the detection pixel includes first and second detection pixels sharing a current-voltage conversion unit, and
the current-voltage conversion unit includes a predetermined number of log transistors that convert the photocurrent into a logarithmic voltage, and a predetermined number of transimpedance amplifiers that invert and amplify the logarithmic voltage.

(10) The solid-state imaging element according to (3), in which:
the grayscale pixel includes a transfer transistor that transfers charge from a photoelectric conversion element to a floating diffusion layer, a reset transistor that initializes the floating diffusion layer, an amplification transistor that amplifies a voltage of the floating diffusion layer, and a selection transistor that outputs a signal of the voltage as the grayscale signal according to a predetermined selection signal;
the detection pixel includes a log transistor that converts the photocurrent into a logarithmic voltage, and a transimpedance amplifier that inverts and amplifies the logarithmic voltage; and
the transfer transistor, the reset transistor, the amplification transistor, the selection transistor, the log transistor, and the transimpedance amplifier are dispersedly arranged in a first layer and a second layer.

(11) The solid-state imaging element according to (10), in which
the transfer transistor, the log transistor, and the transimpedance amplifier are arranged in the first layer, and
the reset transistor, the amplification transistor, and the selection transistor are arranged in the second layer.

(12) The solid-state imaging element according to (10), in which
the transfer transistor and the log transistor are arranged in the first layer, and
the reset transistor, the amplification transistor, the selection transistor, and the transimpedance amplifier are arranged in the second layer.

(13) The solid-state imaging element according to (3), in which:
the detection pixel includes a log transistor that converts the photocurrent into a logarithmic voltage, and a transimpedance amplifier that inverts and amplifies the logarithmic voltage;
among the detection-side wells, a well of the log transistor is connected to a first power supply line; and
among the detection-side wells, a well of the transimpedance amplifier and the grayscale-side well are commonly connected to a second power supply line.

(14) The solid-state imaging element according to (13), in which
a power supply voltage of the first power supply line is a negative voltage lower than a predetermined reference voltage.

(15) The solid-state imaging element according to (2), in which
an area of the detection pixel is the same as that of the pixel region, and
a TI of the detection pixel is reduced as compared with the pixel region.

(16) The solid-state imaging element according to (15), in which
the TI includes an RDTI.

(17) The solid-state imaging element according to (15), in which
the TI includes an FTI.

(18) The solid-state imaging element according to any one of (15) to (17), in which
an area of the detection pixel is the same as that of the pixel region, and
the pixel region is divided into a plurality of unit regions.

(19) The solid-state imaging element according to any one of (15) to (18), in which
the detection pixel includes first and second detection pixels sharing a current-voltage conversion unit, and
the TI is formed on an outer periphery of the first detection pixel and an outer periphery of the second detection pixel.

(20) The solid-state imaging element according to (1), in which:
a predetermined number of the grayscale pixels and a predetermined number of the non-grayscale pixels are arranged in a two-dimensional lattice pattern on a predetermined light receiving surface;
each of the grayscale pixels includes a photoelectric conversion element; and
an area of a photoelectric conversion element of the grayscale pixel adjacent to the non-grayscale pixel on the light receiving surface is different from an area of a photoelectric conversion element of the grayscale pixel not adjacent to the non-grayscale pixel.

(21) The solid-state imaging element according to (20), in which
the non-grayscale pixel is a detection pixel that detects, as an address event, that an amount of change in a photocurrent generated by photoelectric conversion exceeds a predetermined threshold.

(22) the Solid-state Imaging Element According to (20) or (21), in which
an area of a photoelectric conversion element of the grayscale pixel adjacent to the non-grayscale pixel and arranged in the same row or column as the non-grayscale pixel is different from an area of a photoelectric conversion element of the grayscale pixel not adjacent to the non-grayscale pixel.

(23) The solid-state imaging element according to any one of (20) to (22), in which
shapes of photoelectric conversion elements of a pair of grayscale pixels adjacent to the non-grayscale pixel and arranged in the same row or column are asymmetric.

### REFERENCE SIGNS LIST

100 Imaging device
110 Imaging lens
120 Recording unit
130 Control unit
200 Solid-state imaging element
201 Pixel chip
202 Circuit chip
220 Vertical scanning circuit
230 Output unit
240 Column ADC
250 Load MOS circuit
260 Lower pixel region
270 X arbiter
280 Y arbiter
301 to 304, 403, 404 Shared block
305 Grayscale pixel
306 Unit region
311 to 314, 311-1, 311-2, 311-3, 311-4, 312-1, 312-4, 313-1,
313-2, 313-3, 313-4, 411, 412 Photoelectric conversion element
319, 319-1, 319-2, 419, 419-1, 419-2 Power supply line
321 to 324 Transfer transistor
331 Reset transistor
332 Amplification transistor
333 Selection transistor
334 Floating diffusion layer
390, 490 Well
391, 491 P well
401, 402 EVS pixel
411-1 Charge extraction port
420 Current-voltage conversion unit
421, 422, 426 Log transistor
423, 424 TIA
425 Current source transistor
427 Binning transistor
430 Buffer
431, 432, 445, 452, 454 nMOS transistor
440 Subtractor
441, 443 Capacitor
442, 444, 451, 453 pMOS transistor
450 Quantizer
460 Transfer unit
511 Microlens
512 Color filter
521 RDTI
522 FTI
530 Transistor arrangement region
531 Upper layer
532 Lower layer
12031 Imaging section

1. A solid-state imaging element comprising
a pixel region in which a predetermined number of grayscale pixels for generating a grayscale signal according to an amount of charge generated by photoelectric conversion are arranged, and
a non-grayscale pixel not corresponding to the grayscale pixel and in which a trench isolation (TI) having a pattern different from that of the pixel region is formed.

2. The solid-state imaging element according to claim 1, wherein
the non-grayscale pixel includes a detection pixel that detects, as an address event, that an amount of change in a photocurrent generated by photoelectric conversion exceeds a predetermined threshold.

3. The solid-state imaging element according to claim 2, wherein
the TI includes a full trench isolation (FTI), and
the FTI insulates a grayscale-side well that is a well of the grayscale pixel and a detection-side well that is a well of the detection pixel.

4. The solid-state imaging element according to claim 3, wherein:
the detection pixel includes a photoelectric conversion element and a current-voltage conversion unit;
the current-voltage conversion unit includes a predetermined number of log transistors that convert the photocurrent into a logarithmic voltage, and a predetermined number of transimpedance amplifiers that invert and amplify the logarithmic voltage; and
the FTI is formed on an outer periphery of the detection pixel when viewed from an optical axis direction.

5. The solid-state imaging element according to claim 4, wherein
the log transistor is arranged in the detection pixel when viewed from an optical axis direction.

6. The solid-state imaging element according to claim 4, wherein
the log transistor and the transimpedance amplifier are arranged in the detection pixel when viewed from an optical axis direction.

7. The solid-state imaging element according to claim 4, wherein
the FTI is formed on an outer periphery of a region in which a pair of grayscale pixels are arranged, an outer periphery of a region in which the log transistor is arranged, and an outer periphery of a region in which the transimpedance amplifier is arranged.

8. The solid-state imaging element according to claim 4, wherein
at least one of the predetermined number of log transistors is diode-connected.

9. The solid-state imaging element according to claim 3, wherein
the detection pixel includes first and second detection pixels sharing a current-voltage conversion unit, and
the current-voltage conversion unit includes a predetermined number of log transistors that convert the photocurrent into a logarithmic voltage, and a predetermined number of transimpedance amplifiers that invert and amplify the logarithmic voltage.

10. The solid-state imaging element according to claim 3, wherein:
the grayscale pixel includes a transfer transistor that transfers charge from a photoelectric conversion element to a floating diffusion layer, a reset transistor that initializes the floating diffusion layer, an amplification transistor that amplifies a voltage of the floating diffusion layer, and a selection transistor that outputs a signal of the voltage as the grayscale signal according to a predetermined selection signal;
the detection pixel includes a log transistor that converts the photocurrent into a logarithmic voltage, and a transimpedance amplifier that inverts and amplifies the logarithmic voltage; and
the transfer transistor, the reset transistor, the amplification transistor, the selection transistor, the log transistor, and the transimpedance amplifier are dispersedly arranged in a first layer and a second layer.

11. The solid-state imaging element according to claim 10, wherein
the transfer transistor, the log transistor, and the transimpedance amplifier are arranged in the first layer, and
the reset transistor, the amplification transistor, and the selection transistor are arranged in the second layer.

12. The solid-state imaging element according to claim 10, wherein
the transfer transistor and the log transistor are arranged in the first layer, and
the reset transistor, the amplification transistor, the selection transistor, and the transimpedance amplifier are arranged in the second layer.

13. The solid-state imaging element according to claim 3, wherein:
the detection pixel includes a log transistor that converts the photocurrent into a logarithmic voltage, and a transimpedance amplifier that inverts and amplifies the logarithmic voltage;
among the detection-side wells, a well of the log transistor is connected to a first power supply line; and
among the detection-side wells, a well of the transimpedance amplifier and the grayscale-side well are commonly connected to a second power supply line.

14. The solid-state imaging element according to claim 13, wherein
a power supply voltage of the first power supply line is a negative voltage lower than a predetermined reference voltage.

15. The solid-state imaging element according to claim 2, wherein
an area of the detection pixel is the same as that of the pixel region, and
a TI of the detection pixel is reduced as compared with the pixel region.

16. The solid-state imaging element according to claim 15, wherein
the TI includes a rear deep trench isolation (RDTI).

17. The solid-state imaging element according to claim 15, wherein
the TI includes an FTI.

18. The solid-state imaging element according to claim 15, wherein
an area of the detection pixel is the same as that of the pixel region, and
the pixel region is divided into a plurality of unit regions.

19. The solid-state imaging element according to claim 15, wherein
the detection pixel includes first and second detection pixels sharing a current-voltage conversion unit, and
the TI is formed on an outer periphery of the first detection pixel and an outer periphery of the second detection pixel.

20. The solid-state imaging element according to claim 1, wherein:
a predetermined number of the grayscale pixels and a predetermined number of the non-grayscale pixels are arranged in a two-dimensional lattice pattern on a predetermined light receiving surface;
each of the grayscale pixels includes a photoelectric conversion element; and
an area of a photoelectric conversion element of the grayscale pixel adjacent to the non-grayscale pixel on the light receiving surface is different from an area of a photoelectric conversion element of the grayscale pixel not adjacent to the non-grayscale pixel.

21. The solid-state imaging element according to claim 20, wherein
the non-grayscale pixel includes a detection pixel that detects, as an address event, that an amount of change in a photocurrent generated by photoelectric conversion exceeds a predetermined threshold.

22. The solid-state imaging element according to claim 20, wherein
an area of a photoelectric conversion element of the grayscale pixel adjacent to the non-grayscale pixel and arranged in the same row or column as the non-grayscale pixel is different from an area of a photoelectric conversion element of the grayscale pixel not adjacent to the non-grayscale pixel.

23. The solid-state imaging element according to claim 20, wherein
shapes of photoelectric conversion elements of a pair of grayscale pixels adjacent to the non-grayscale pixel and arranged in the same row or column are asymmetric.
